(19) United States
(12) Patent Application Publication
(10) Pub. No.: US 2018/0277279 A1
(43) Pub. Date: Sep. 27, 2018

(54) Graphene Containing Composition, Multilayered Hydrogen Graphene Composition, Method of Making Both Compositions, and Applications of Both Compositions

(71) Applicants: David Brereton, Chilliwack (CA); Timothy Brereton, Williams Lake (CA); Axel Winkelmann, Niagara on the Lake (CA)

(72) Inventors: David Brereton, Chilliwack (CA); Timothy Brereton, Williams Lake (CA); Axel Winkelmann, Niagara on the Lake (CA)

(21) Appl. No.: 15/820,972

(22) Filed: Nov. 22, 2017

Related U.S. Application Data
(60) Provisional application No. 62/425,740, filed on Nov. 23, 2016.

(51) Int. Cl. H01B 1/04; H01L 31/028; H05K 9/00; B01D 17/02; C02F 1/28; C02F 1/68

(52) U.S. Cl. CPC H01B 1/04; H01L 31/028; H05K 9/0081; B82Y 30/00; C02F 1/283; C02F 1/681; B01D 17/0202

(57) ABSTRACT

A graphene containing composition comprises a mixture of multilayered graphene and graphite, which present many desirable properties and have numerous applications in various industries. A process generates said graphene containing composition in water-based cosolvents with relatively gentle mechanical force. A process generates a hydrogen bonded graphene laminate or multilayered hydrogen graphene, which comprises a readily identifiable multilayered graphene component and a graphite component. In the hydrogen graphene laminate (multilayered hydrogen graphene composition), the hydrogen bonding separates the layers and weakens the Van der Waals forces between the graphite sheets sufficiently to produce laminate layers of graphene. Multilayered hydrogen graphene composition also presents many desirable properties and has numerous applications in various industries.

This application claims the benefit of previously filed U.S. Provisional Application No. 62/425,740 filed on Nov. 23, 2016 and is hereby incorporated by reference herein.

### TECHNICAL FIELD

A process generates multilayer graphene in water-based cosolvents using relatively gentle mechanical force. A graphene containing composition created by the process comprises a mixture of multilayered graphene and graphite, which present many desirable properties and have numerous applications in various industries. A process generates a hydrogen bonded graphene laminate or multilayered hydrogen graphene, which comprises a readily identifiable multilayered graphene component and a graphite component. In the hydrogen graphene laminate, the hydrogen bonding separates the layers and weakens the Van der Waals forces between the graphite sheets sufficiently to produce laminate layers of graphene.

### BACKGROUND

Graphene is a material having a monolayer or a few layers of carbon atoms. Within each layer, the carbon atoms are covalently bonded to form a honeycomb lattice, generally adjacent hexagons. The honeycomb lattice may be flat or nearly flat. Considering the diameter of a single carbon atom, each graphene sheet is ultra-thin, and therefore sometimes a single graphene sheet is considered as a two-dimensional structure. Graphite, on the other hand, contains a massive multilayer honeycomb lattice structure of carbon atoms, wherein each layer of honeycomb lattice stacks on top of each other. Each honeycomb layer within graphite resembles the single sheet of graphene. (Zhu et al, “Graphene and Graphene Oxide: Synthesis, Properties, and Applications,” Advanced Materials, 22(35): 3906-24, Sep. 15, 2010). Geim and Novoselov published in 2004 an article in “Science” describing a method of preparing graphene using Scotch tape. Graphene as a new material with many desirable properties has caught great attention and has been intensively investigated ever since. Due to their pioneering work in graphene research, Geim and Novoselov received the Nobel Prize in physics in 2010. Although great efforts have been made by scientists in the field, the manufacturing and commercialization of graphene products still face many hurdles.

Pristine graphene is graphene in its original or ideal state, having a perfect or nearly perfect planar single layer honeycomb structure. In theory, pristine graphene has very few or even no structural defects that degrade its properties and has minimal oxygen functionalities or is essentially free of oxygen. In practice and as used herein, graphene having small amounts of structural defects and trace amounts of oxygen, either single layer or a few layers (e.g. less than 10 layers), can be still considered as pristine graphene.

Over the years, scientists and researchers in the field have developed several practical methods to generate pristine graphene or pristine quality graphene: mechanical exfoliation, chemical vapor deposition (CVD) on substrate surfaces, substrate free gas-phase synthesis of graphene, graphene oxide exfoliation, and exfoliation of graphite in solvents. Geim and Novoselov developed a practical mechanical exfoliation method using Scotch™ tape to peel a single layer of pristine graphene from bulk graphite materials. Mechanical exfoliation can create very high quality graphene for lab research, but it is rather limited in scaling up for apparent reasons. The CVD method starts with heating up hydrocarbon gas and substrate. As the temperature lowers, carbon atoms deposit on the surface of the substrate to form single layer graphene. Alternatively, silicon carbide (SiC) can be used to replace hydrocarbon (epitaxial growth). For SiC system, very high temperature and high vacuum have to be deployed in order to sublime Si atoms and form graphene as a result. CVD and epitaxial growth are sensitive to the conditions, sometimes extreme conditions, and require a lot of refinement of experimental procedures, which is not suitable for low cost and large scale production. Pristine graphene can also be synthesized in gas phase without substrate. However, such methods also require some extreme conditions and special equipment. (Zhu et al, “Graphene and Graphene Oxide: Synthesis, Properties, and Applications,” Advanced Materials, 22(35): 3906-24, Sep. 15, 2010; and U.S. Pat. No. 9,388,048).

Graphene oxide (GO) exfoliation is a common method to produce graphene like materials, which comprises two steps: oxidation of graphite and reduction of graphene oxide. Specifically, graphite is treated with strong oxidizing agents to yield graphene oxide, a nonconductive hydrophilic carbon material. Hummer's oxidation method is the most commonly used one, wherein graphite is oxidized by potassium permanganate (KMnO₄) and sodium nitrate (NaNO₃) in concentrated sulfuric acid (H₂SO₄). (Marcano et al, “Improved Synthesis of Graphene Oxide”, ACS Nano, 4(8): 4806-4814, 2010). In recent years, some scientists have modified Hummer's methods to improve percent yield and the quality of final products and to make the purification less difficult.

In the oxidation reaction, oxygen functionalities are introduced to the sheet structures within graphite. There groups are more bulky causing increased spacing between the layers that make up the stacked structure within graphite. As the interlayer spacing increases, the van der Waals forces holding the sheets together fade accordingly and make exfoliation of GO sheets much easier. Graphene oxide itself has many applications in various scientific fields. However, due to the added oxygen functionalities, GO is distinctively different from graphene in several key factors. Specifically, GO is not conductive (i.e. insulator) due to the disruption of delocalized electron networks by oxygen functionalities throughout the graphene honeycomb lattice. GO is generally hydrophilic and is soluble or easily dispersible in polar solvents, making it easier to handle and manufacture. On the contrary, pristine graphene is a very good electrical and thermal conductor but is generally hydrophobic. Direct exfoliation of pristine graphene from bulk graphite is rather challenging due to strong interlayer van der Waals forces.

Graphene oxide can be converted to reduced graphene oxide (rGO), a graphene like material, through a number of methods. Some examples of reduction methods include: treatment of GO with strong reducing agents, such as hydrazine hydrate; exposure of GO to hydrogen plasma; exposure of GO to powerful pulsed light; exposure of GO to urea under heat; direct heating of GO under very high temperature; and electrochemical production. These chemical, thermal, photochemical, and electrochemical approaches in theory should produce high quality of rGO resembling pristine graphene. However, in real applications, these reduction methods suffer various significant disadvantages. Some of the reduction methods require extreme conditions, toxic reducing agents, or a combination of both. For chemical reduction, the removal of all the chemical regents from the final product is difficult, if possible at all, adding unnecessary impurities to rGO. Some reduction methods are expensive to implement with low percent yield and are hard to scale up for mass production. Due to extreme conditions and/or toxic chemicals used in the reduction reactions, the final product of rGO normally contains structural defects in the graphene honeycomb lattice and inevitably further contains certain amounts of impurities and/or residual chemicals. More importantly, reduction of GO is unable to fully remove the oxygen functionalities from GO, and therefore the resulting product of rGO always contains residual amount of oxygen atoms. As shown above, the existence of oxygen atoms disrupts the structure of graphene honeycomb lattice leading to undesirable properties, such as electrical conductivity of rGO considerably less than pristine graphene. Therefore, rGO is not real pristine graphene. The problem of residual oxygen atoms in rGO is evidenced by commercial products. For example, the properties of an rGO product listed on the Graphenea website shows that it contains 13-22% oxygen. (“Reduced Graphene Oxide: Properties, Applications and Production Methods,” Graphenea, May 20, 2015, http://www.azonano.com/article.aspx?ArticleID=4041). As a comparison, the same website shows that GO product normally contains about more than 40% of oxygen. Pristine graphene, however, is essentially free of oxygen. Some recent attempts in the field have lowered the oxygen level in rGO products to about 10% (U.S. Pat. No. 9,413,007). Such level is still not as ideal as pristine graphene. Another issue in the art is that some of the above mentioned terms, such as graphene, graphene oxide, reduced graphene oxide, and pristine graphene are used loosely or interchangeably, causing significant confusion.

Graphite exfoliation in solvents is another commonly used method to produce pristine graphene. In graphene oxide exfoliation, the strong interlayer van der Waals forces within graphite are largely overcome by the repulsive forces between the introduced oxygen functionalities on each graphene sheet. Direct exfoliation using mechanical force from bulk graphite is more difficult than GO exfoliation because it does not enjoy the benefit of interlayer repulsive force created by the added oxygen atoms. This process is particularly difficult to carry out in polar solvents, e.g. water, because graphene sheets are strongly hydrophobic. Adding organic solvents along with surfactants and/or acids can weaken the interlayer forces within graphite and prevent the separated graphene sheets from flocculating, thus alleviating the problem encountered in mechanical exfoliation (U.S. Pat. No. 9,388,049). Some examples of the mechanical forces employed in certain the graphite exfoliation procedures include high speed stirring and sonication. However, addition of surfactants for stabilizing graphene sheets creates its own problems, such as difficulties in purifying final products. Further, both graphene oxide (GO) exfoliation and mechanical exfoliation are known to damage the crystalline structure of the graphene.

### SUMMARY

This invention relates to a low cost graphene containing composition having natural binding ability, which is easy to manufacture compared to other commercial graphene products on the market. The pristine condition of the graphene component gives its many desirable properties, including but not limited to being less hydrophobic and predominantly hydrophilic than other commercial graphene products, intact crystalline structure within the graphene single sheet, good electrical conductivity, and essentially free of oxygen. The desirable properties of the current graphene containing composition make it suitable for various applications, such as an additive in paint/coating/concrete, Faraday Film, or battery material. This invention further relates to a multilayered or laminate layered hydrogen bonded graphene that has hydrogen bonds in the layers of both the graphene component and the graphite component, allowing sufficient separation of the graphite layers to convert into a graphene laminate. The multilayered hydrogen bonded graphene composition (hereinafter referred to as multilayered hydrogen graphene) represents the first practical invention of a 3-dimensional graphene having superior electrical and thermal conductivity as compared to pristine single layer graphene. This new composition of hydrogen intercalated graphene is a more accurately described as multilayered/laminate hydrogen graphene.

One embodiment relates to a graphene containing composition comprising:
(a) a graphene component; and
(b) a graphite component
wherein the graphene component comprises monolayer graphene, multilayered graphene, or a combination thereof,
further wherein the multilayered graphene comprises less than about 10 layers of carbon atoms, and
wherein the composition comprises at least about 3.5% of the graphene component.

Another embodiment relates to a method for using graphene containing composition comprising the steps of:
(a) providing the graphene containing composition; and
(b) adding the graphene containing composition to a product selected from the group consisting of paints, coatings, cement, concrete, steel, plastics, a sealant, an anti-corrosion agent, an anti-weathering agent, a salt water shield, an anti-fouling agent, a conductivity enhancing agent, a thermal insulation barrier, an electromagnetic pulse barrier, a radio frequency modulation barrier, a magnetic levitation agent, a fire resistant agent, a heat conductor, a battery, a capacitor storage, adhesion promoters, anti-friction additives, flooring, ships hulls, sporting goods, a fire retardant, a de-icing agent, solar panels, electronic circuits, sensors, and an insulation material.

Another embodiment relates to a method of making a graphene containing composition comprising:
mixing isopropyl alcohol, acetone, distilled water, and graphite water to form a graphite suspension;
high speed blending the graphite suspension at a temperature of at least about 120° F. from about 1 hour to about 10 hours;
applying vacuum to the graphite suspension during blending;
heating the graphite suspension during blending; and
drying the blended graphite suspension to obtain the graphene containing composition;
wherein the distilled water is ionized water.

Another embodiment relates to a multilayered hydrogen graphene composition comprising:
(a) hydrogen graphene; and
(b) hydrogen graphite
wherein the hydrogen graphene contains hydrogen intercalated with graphene layers,
wherein the hydrogen graphite contains hydrogen intercalated with graphite layers,
wherein the composition comprises at least 3% of hydrogen graphene,
wherein the hydrogen graphene contains from at least 2 layers of graphene to about 8 layers of graphene, and
wherein the hydrogen graphite contains from about 20 layers of graphite to about 100 layers of graphite.

Another embodiment relates to a method for using multilayered hydrogen graphene composition comprising the steps of:
(a) providing the multilayered hydrogen graphene composition; and
(b) adding the multilayered hydrogen graphene composition to a product selected from the group consisting of a Berry Phase switch, a spintronic induction based transistor, a superconductor, sensors, embedded electronics, coating, concrete, cement, paints, an additive, composites, sporting goods, plastics, protecting film, friction coating, steel, rubber, polymers, thermally conductive materials, filtration materials, supercapacitors, building materials, an anti-corrosive agent, an electromagnetic pulse barrier, a radio frequency modulation barrier, wires, capacitors, glass, solar panels, and U/V protecting agents.

Another embodiments relates to a method of making a multilayered hydrogen graphene composition comprising:
mixing isopropyl alcohol, acetone, distilled water to an ionic solvent
soaking graphite in the ionic solvent for from about 8 to about 24 hours to form a presoaked graphite suspension;
high speed blending the presoaked graphite suspension at a temperature of at least about 120° F. from about 1 hour to about 10 hours;
applying vacuum to the presoaked graphite suspension during blending;
heating the presoaked graphite suspension during blending; and
drying the blended graphite suspension to obtain the multilayered hydrogen graphene composition;
wherein the distilled water is ionized water.

### BRIEF DESCRIPTION OF DRAWINGS

FIG. 1A depicts, in one embodiment, Raman spectra of graphite (top) and pristine graphene (bottom); and FIG. 1B depicts, in one embodiment, Raman spectra of multilayered graphene (top) and single layer graphene (bottom).

FIG. 2 depicts, in one embodiment, a Raman spectrum of commercial graphene oxide compound.

FIG. 3 depicts, in one embodiment, a Raman spectrum of one embodiment of graphene containing composition.

FIG. 4 depicts, in one embodiment, the results of SEM test on the present graphene containing composition obtained in Example 1.

FIG. 5 depicts, in one embodiment, the results of a second SEM scan on the present graphene containing composition obtained in Example 1.

FIG. 6A depicts, in one embodiment, one SEM scan on the reference graphene oxide sample (d₀₂₀=0.210 nm; d₀₀₂=0.356 nm); and FIG. 6B, FIG. 6C, and FIG. 6D depict three STEM scans on the reference graphene oxide sample, respectively.

FIG. 7A depicts, in one embodiment, one SEM scan on the present graphene containing composition obtained in Example 1 (d₀₂₀=0.213 nm, d₀₀₂=0.345 nm); and FIG. 7B depicts, in one embodiment, one STEM scan on the present graphene containing composition obtained in Example 1. (Scan on left shows great crystal intact status in upper right hand corners of the picture on the left.)

FIG. 8A, FIG. 8B, FIG. 8C, and FIG. 8D depict, in one embodiment, four STEM scans on the present graphene containing composition obtained in Example 1, respectively.

FIG. 9A depicts, in one embodiment, acid damages after 7 days on a metal surface covered with regular anti-corrosion coating without the infused graphene containing composition; and FIG. 9B depicts, in one embodiment, anti-corrosion test on the same metal surface covered with the graphene infused anti-corrosion coating. (No damage after 7 days).

FIG. 10 depicts, in one embodiment, SEM side view of multilayered hydrogen graphene composition. Individual layers can be seen and counted both in the 2-6 layered graphene flakes, and the larger graphite stacks that have been intercalated and the Van Der Wall forces weakened or replaced by hydrogen bonding. The above scan is of the many layered stacks of graphite at beginning of intercalation time period before they have intercalated fully and extra space had formed in between the graphene layers. The figure illustrates tight packing of graphite stacks before intercalation and hydrogen bonding has developed in between the layers of graphite.

FIG. 11 depicts, in one embodiment, Sputtering plasma tests burning off surface hydrogen in initial, 5 second, and 30 second increments with average test results highlighted in the box of C₄H₆ calculated as average of test results. (Comparison of ratios H⁺, C₃H₅⁺, C₄H₇⁺, C₆H₅⁺, C₇H₇⁺ normalized to C⁺ between HOPG and the graphene before (upper) and after sputtering for 5 s (middle) and 30 s (bottom).

FIG. 12 depicts, in one embodiment, Sputtering plasma tests burning off surface hydrogen in initial, 5 second, and 30 second increments with both reference and invention samples tested. (Comparison of ratios H⁻/C⁻ and CₙH_/Cₙ⁻) between HOPG and the graphene before (upper) and after sputtering for 5 s (middle) and 30 s (bottom).

FIG. 13 depicts, in one embodiment, elemental analysis of multilayered hydrogen graphene composition using CHN Analysis machine.

FIG. 14 depicts, in one embodiment, SEM scan of graphene flakes with multilayered hydrogen graphene.

FIG. 15 depicts, in one embodiment, STEM scan of calcium doped-intercalated into multilayered graphene flake.

FIG. 16 depicts, in one embodiment, carbon STEM scan of multilayered hydrogen graphene flake.

FIG. 17 depicts, in one embodiment, SEM pictures of multilayered hydrogen graphene.

FIG. 18 depicts, in one embodiment, various multilayered hydrogen graphene flakes under scanning electron microscope.

FIG. 19 depicts, in one embodiment, various multilayered hydrogen graphene flakes under scanning electron microscope.

FIG. 20 depicts, in one embodiment, proton NMR spectrum of the multilayered hydrogen graphene composition.

FIG. 21 depicts, in one embodiment, carbon NMR spectrum of the multilayered hydrogen graphene composition.

FIG. 22 depicts, in one embodiment, exfoliation tests on glass wafer for electrical conductivity and resistance of the multilayered hydrogen graphene composition. These test results calculate to 0.000214 siemens per meter for electrical conductivity which suggests incredibly fast electron mobility.

FIG. 23 depicts, in one embodiments, the multilayered hydrogen bonded graphene composition mixed with water and tested on wafers.

FIG. 24 depicts, in one embodiment, multilayered/laminate hydrogen graphene painted/3D printed on plastic sheets as flexible electronic circuits.

FIG. 25 depicts, in one embodiment, intact graphene crystals (pristine crystals) in the multilayered hydrogen graphene composition under SEM scan.

FIG. 26 depicts, in one embodiment, multilayered hydrogen graphene composition with hydrogen bubbles that were developed under −32° C. (Scans taken at 4D labs, Simon Fraser University). (The light arrows in the figure indicate hydrogen graphene layers. Top left: 4˜6 hydrogen graphene layers; Top right: 4˜6 hydrogen graphene layers; Bottom left: 11 hydrogen graphene layers; Bottom right: 10 hydrogen graphene layers. The dark arrows in the bottom right panel indicate hydrogen bubbles.)

FIG. 27 depicts, in one embodiment, SEM of multilayered hydrogen bonded graphene composition. (The light arrow in the left panel indicates 10 hydrogen bonded graphene layers. The light arrow in the right panel indicate a random yet complete overlapping sheets of graphite-graphene when dissolved in water then placed onto test wafer. In the right panel, the darker area indicates graphite sheets and lighter area depicts thin layers of graphene.)

FIG. 28 depicts, in one embodiment, the structure of multilayered hydrogen graphene composition. (The left panel indicates an overlapping structure. From left to right: 2-8 layers of hydrogen bonded graphene; 20-100 layers of loosely layered graphite after exfoliation process; 2-8 layers of hydrogen bonded graphene. The right panel indicates a flake profile. From left to right: 3 microns of exfoliated hydrogen graphene layers still attached to graphite stack; 20 microns of graphite stack; 3 microns of exfoliated hydrogen graphene layers still attached to graphite stack.)

FIG. 29 depicts, in one embodiment, AFM test of multilayered hydrogen graphene composition. (The left panel depicts number of hydrogen graphene layers. The right panel indicates: d₅₀=30 layers; d₉₀=107 layers; #Layers (1-10)=4; Graphene Content=3.6%).

FIG. 30 depicts, in one embodiment, multilayered hydrogen graphene spintronic switch, hydrogen bonded graphene induction transistor, and Berry Phase switch. (“Spintronic Transistor By Induction With Hydrogen Bonded Graphene”; “Multi-Layered Graphene With Hydrogen Bonds”; Inner transistor circuit effected by outer circuit magnetic fields to induce slight changes in election flow inducing voltage swing (in on example) ½ microvolt to 4 milli volts (induction causes slight pause to electrons enough to trigger voltage swing that can be functionalized as logic gates creating on-off or 1 & 0 transistoring effect)).

FIG. 31 depicts, in one embodiment, solar cells painted with graphene containing composition or multilayered hydrogen bonded graphene composition.

### DETAILED DESCRIPTION

This disclosure refers to a method of liquid phase exfoliation of graphite powder into a graphene/graphite liquid slurry followed by a conversion into a graphene/graphite blend composition, which can be manufactured inexpensively. The graphene in the current invention is less hydrophobic than graphene obtained with other methods. This allows the current graphene containing product to have both the benefits of graphene and the generally hydrophilic properties needed for it to mix into multiple materials without aggregating or forming clumps. The present invention also relates to a graphene containing composition produced using the liquid phase exfoliation method under partial or full vacuum and applications of the graphene containing composition. The graphene generated in the current process has less than 4% oxygen by weight. Preferably, the present graphene is essentially free of oxygen and has the characteristics of pristine graphene. Due to very low amount of oxygen impurity, the graphene containing composition does not need to be washed to remove oxide. It is further unexpected that the graphite component in the graphene containing composition functions as a built-in binder eliminating the need of additional binder, which further lowers the cost. The graphite in the graphene containing composition greatly reduces the amount of pinholes or fisheyes in graphene sheets, making the graphene containing composition corrosion resistant. The graphene containing composition has varieties of applications including but not limited to additives in cement, paints, and coatings.

There are many commercial graphene products with various grades on the market, which are gauged by graphene content, oxygen level, content of other impurities, and defects in graphene sheets. Some notable disadvantages in these commercial graphene products include, among others, prohibitive high price caused by complicated manufacturing processes, high oxide level if prepared through GO exfoliation (oxidation/reduction cycle) and defects (e.g. pinholes/fisheyes) in graphene layers. Among other things, harsh chemicals and shear forces applied to graphite during exfoliation tend to damage or destroy crystalline structure of the graphene hexagonal.

Graphane is a two-dimensional polymer of carbon and hydrogen with the formula unit (CH)ₙ where n is large. Graphane is a form of hydrogenated graphene. Among the unique properties of hydrogen graphene composition are that the crystals are pristine, there are no pin holes, no oxides, it is hydrophilic in water, binds readily, is sprayable, is 3-dimensional, is superconductive at room temperature and has a magnetic field. The attributes of current hydrogen graphene composition are defined through its properties, such as electrical conductivity, which are sometimes different than that of non-hydrogen bonded graphene. In the case of electrical and thermal conductivity, the current hydrogen graphene composition is vastly superior to non-hydrogen bonded graphene. Current best standards for non-hydrogen bonded graphene electrical conductivity is about 100 Siemens per meter which is available as a silver and graphene paint (Sigma Aldrich Corporation). Electrical conductivity of average graphene products is from about 30,000 to about 60,000 Siemens per meter. In comparison, the conductivity of the present multilayered hydrogen bonded graphene is about 0.000214 Siemens per meter.

The instant graphene has a magnetic field, is multilayered and has intercalated hydrogen and optionally doped calcium and nitrogen intercalated in the same process of solvent based exfoliation of graphite. These doping agents were found in tests conducted at the University of Singapore on the present hydrogen graphene composition and are natural agents in the ionic distilled water utilized in the invention. Fluorene, boron, potassium, lithium and sulphur can also be used for doping by adding them into liquid solution and allowing intercalation over an extended time period in liquid in-situ in the solvent and distilled water solution before high speed shear mixing.

Method of Making Graphene Containing Composition

The present method of manufacturing graphene containing composition is similar to Robert Murray-Smith's method/formula, which was disclosed in a 2014 YouTube video. (https://www.youtube.com/watch?v=fvqkH0WLvyc). Robert Murray-Smith's open source method, a solvent based graphite exfoliation method, was designed for producing graphene ink. The open source method includes blending water-acetone cosolvent with graphite for a prolonged period of time to create graphene in liquid form. Water or acetone alone, when blended with graphite powder, is unable to convert graphite into graphene. But if graphite, water, and acetone are mixed together in an appropriate mass fraction, these three materials in a gentle high speed mixing process will exfoliate the graphite and produce graphene containing materials. This liquid exfoliation process undergoes 1 to 10 hours of mixing. When the process of mixing is complete, graphene will be suspended in the liquid portion of the mixture. Longer mixing time normally leads to higher percent yield of graphene. However, prolonged mixing time may degrade the quality of resulting graphene. Therefore, optimal time was selected to maximize the graphene production and minimize side reactions and the amount of impurities.

Even though having achieved some success, Robert Murray-Smith's open source method was rudimentary and ineffective for commercial applications and was released to the public for hobbyists wanting to experiment with graphene. For example, the open source method is only good for production of graphene in suspension. If the resulting ink is painted onto a surface it has high ohms resistance which inhibits its conducting properties. To achieve lower ohms resistance, the original open source formula requires exfoliation. The present disclosure includes at least the following improvements to the open source methods: a variety of suitable organic solvents may be used, such as acetone ethyl acetate, butane, methyl-ethyl-ketone, trichloroethylene, tetrachloroethylene, ethanol or a combination thereof; addition of isopropyl alcohol to cosolvent; optimal mixing time; and various ratios among different solvents.

The graphite powder with various meshes and water-acetone cosolvent can be placed into a mixing drum. The mixture is subsequently mixed at high speed, cavitated, and/or sonicated for 1 to 10 hours. The blending can be performed under partial or complete vacuum. Some of the best results were obtained under the conditions of mixing for 5 hours at 13,000 RPM. An important distinction between the original Murray-Smith liquid formula and the current method is that the present invention requires ionized distilled water, while the open source formula specifically requires de-ionized water. The usage of ionized distilled water renders the present invention suitable for commercial production of graphene compositions. During mixing under partial or complete vacuum, the graphite suspension in acetone-water cosolvent begins to boil at low pressure, which assists in the creation of graphene. The mixing vessel heats up naturally during this stage to a temperature of about 120° F. or above. In large scale manufacturing, the best practice is to use a vacuum pump with the mixing vessel to induce the low pressure boiling of the liquid solvents and create the heat needed to assist in the formation of graphene/graphite composition in liquid slurry which then is dried into a graphene containing composition powder. More importantly, mixing under partial vacuum keeps the oxides from forming at a high level.

After mixing is completed, the liquid solution can be poured into settling containers or dried in commercial dryers to become a graphene powder. If the solution is placed into settling containers, a period of 1 to 10 days is required for the graphene to settle at the bottom of the container and fall out of the liquid suspension. A condensing gas column, still, condenser, or other condensing methods can be incorporated in the method to capture and reuse the acetone as it evaporates while the graphene exfoliation liquid suspension is dried. The addition of isopropyl alcohol can improve the flashing properties of the cosolvent when drying the graphene suspension into a powder. In one embodiment, the graphene containing composition takes average 5 to 12 hours to make, and about another 4 hours to dry using electrical drying drums or similar methods.

Properties of Graphene Containing Composition

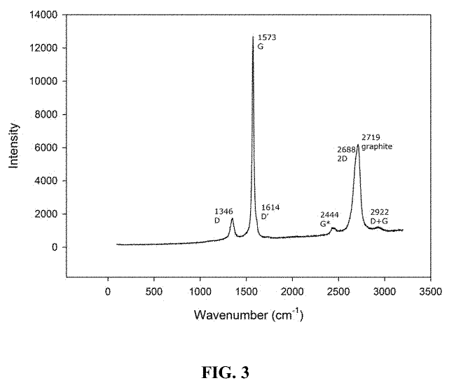

The resulting graphene containing composition contains at least 10.5% of graphene based on the D′ band in the Raman analysis in FIG. 3 and the remaining mass of graphene containing composition is graphite. STEM, SEM and Raman studies indicate that the obtained graphene portion is in pristine condition and multilayered graphene is the main product. The elemental analysis obtained from SEM indicates that oxygen level in graphene samples within the graphene containing composition is no more than 4% by weight. STEM results further indicate that the oxygen level in the present graphene samples is as low as 1% by weight or less, close to background oxygen level of the samples. In other words, the resulting graphene contains very small amount of oxygen, i.e. no more than 4% by weight or less, or is essentially or substantially free of oxygen.

The remaining graphite in the graphene containing composition surprisingly functions as a built-in binder. The left-over graphite in the graphene containing composition eliminates the need of adding additional binders when using graphene. The common practice in graphene industry is to remove all graphite from a graphene/graphite reaction mixture. In contrast, the present invention leaves the graphite in the graphene containing composition to improve its binding capabilities and eliminates the purification step at the same time.

The present graphene containing composition solves a major problem of current art: formation of pinholes or fisheyes in graphene sheets. Pinholes/fisheyes exist in the graphene layer especially when graphene is mixed into or infused into other materials. These pinholes allow corrosive materials to permeate through the graphene layer. In the present graphene containing composition, these pinholes are greatly reduced or are completely removed. Without being bound by any theory, it is believed that the graphite in the present graphene containing composition behaves as a filler that fills in these pinholes or fisheyes within graphene sheets that are not already pristine when mixed into liquids or solid materials.

Applications of Graphene Containing Composition

The benefits of the present graphene containing composition include but not limited to exceptional corrosion control, extra strengthening with light weight, and greatly reduced electrical resistance. Another advantage of the present high quality graphene containing composition over other commercial products is its low cost. Due to simple preparation method and simplified purification process, the present graphene containing composition can cost as low as $1.50 to $2.50 per gram. In comparison, current graphene industry pricing ranges from about $8 per gram to about $150 per gram. The pricing and ease of mass production of present graphene containing composition will allow entrance of graphene products into the fields traditionally very sensitive to the cost of raw materials. Some examples of such fields can include, for example paints and coatings, cement and concrete, steel, and plastics.

Furthermore, the present graphene containing composition has at least the following applications: enhancing strength of materials, enhancing rigidity of materials, enhancing structural forces such as tension, shear, compression, flexoral and resonance/harmonic forces, acting as a sealant, waterproofing materials, protective coating, anti-corrosion agent, anti-weathering agent, salt water shield, anti-fouling agent, conductivity enhancing agent, thermal and insulation barrier, EMP (electromagnetic pulse) barrier, RF (radio frequency) modulation barrier, enhancing computing power, enhancing electronic sensing, enhancing optical applications, magnetic levitation agent, fire resistant agent, heat conductor, battery and capacitor storage. The present invention of graphene containing composition can be mixed or infused into the following: paints and coatings (polyurea-polyurethane, adhesion promoters, varnishes, etc.), concrete (all types including stucco exterior finishes), oil based uses (anti-friction additives etc.), roofs on buildings (additive to tar based coverings and coatings), industrial flooring, ships hulls (anti-fouling paints and corrosion coatings), docks and piers, aqueducts, hydroelectric infrastructure (ELF (Extreme Low Frequencies) & EMP protection), steel infrastructure (additive in steel), steel coatings, concrete bridges and infrastructure, sporting goods, oil recovery, automotive uses, personal protection, heating tiles, thermoelectric applications, fire retardant, additive to new concrete, additive to paint, anti-corrosive applications, aircraft applications including de-icing, automotive applications, tires, glass, buildings and structures, lighting, hydroelectricity, solar panels, electronics, computers, sensors, coating for HVAC and heat pump applications, armor and protective applications, military ordinance coating applications, protective coating for military vehicles, pipelines, Faraday cage applications as protection from EMP for data server farms and control centers, RF Modulation protection from hacking for data server farms, as an insulation material, and battery and conductive applications (super capacitors and long life batteries).

The present graphene containing composition, method of its preparation, characterization of the graphene containing composition, and applications of the graphene containing composition may be further understood in connection with the following Examples and embodiments. In addition, the following non-limiting Examples and embodiments are provided to illustrate the invention.

### Example 1. Method of Manufacturing Graphene Containing Composition

The materials used in the manufacture of graphene containing composition are listed in Table 1.

TABLE 1
Materials Used in the Manufacture
of Graphene Containing Composition

| Material | Amount | |
|---|---|---|
| Isopropyl Alcohol (91%) | 50 | ml |
| Acetone | 700 | ml |
| Ionized Distilled Water^{b} | 250 | ml |
| Graphite Powder^{a} | >50 | grams |

^{a}Depending on final applications, multiple meshes of graphite can be used for making graphene containing composition. For corrosion coating, graphite with 325 mesh is used to make the instant graphene containing composition.
^{b}The total volume of initial graphite suspension is about 1 liter.

These materials are placed into a mixing drum and subsequently mixed at high speed, cavitated, and/or sonicated for 1 to 10 hours under partial or full vacuum. In one embodiment, the optimal mixing condition is mixing for 5 hours at 13,000 RPM. During mixing under partial or complete vacuum, the graphite cosolvent suspension begins to boil at low pressure, which engenders or assists in the creation of graphene. The mixing vessel heats up naturally during this stage to a temperature of about 120° F. or above. In mass production, a vacuum pump coupled with the mixing vessel is recommended to induce the low pressure for boiling off the liquid solvents and create the heat needed to assist in the formation of graphene/graphite composition in liquid slurry, which then is dried into a graphene containing composition powder.

After mixing is completed, the liquid suspension can be poured into settling containers or dried in commercial dryers to obtain a graphene containing composition powder. If the solution is placed into settling containers, a period of 1 to 10 days is required for the graphene to settle at the bottom of the container and fall out of the liquid suspension. As the liquid suspension is dried, acetone in the cosolvent can be recycled using a condensing gas column or still, which may be coupled with mixer and dryer.

Characterization of Graphene Containing Composition

The graphene containing composition produced in Example 1 and reference graphene oxide sample were analyzed using Raman Spectroscopy, SEM (Scanning Electron Microscope), and STEM (Scanning Transmission Electron Microscope) techniques. Without being bound by any theory, testing results and corresponding analysis are provided below.

### Example 2. Raman Spectroscopy

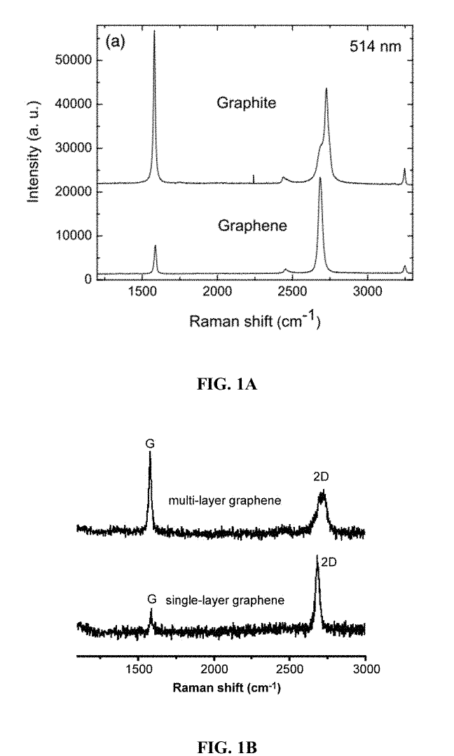

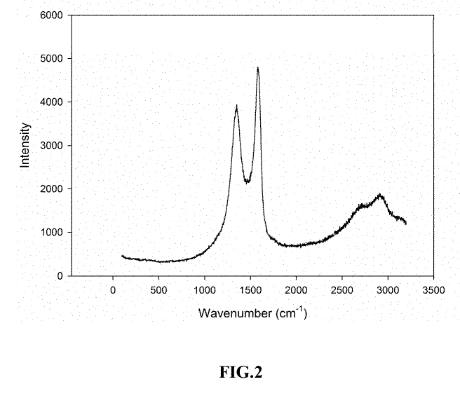

Graphite and monolayer pristine graphene references were analyzed using Raman spectrometer and the corresponding Raman spectra are depicted in FIG. 1 (a). (Reference Raman shift of graphite and graphene provided by Simon Fraser University, BC, Canada). Raman spectra of multilayered graphene and single layer graphene are depicted in FIG. 1(b). (http://devarchive.cnx.org/contents/f06226c5-c2a4-4798-9c75-016acea73cd@2/characterization-of-graphene-by-raman-spectroscopy). The Raman spectrum of commercial graphene oxide compound is depicted in FIG. 2. (Provided by Simon Fraser University, BC, Canada). The Raman spectrum of the present graphene containing composition is depicted FIG. 3. The characterization of primary bands in these spectra is summarized in Table 2.

TABLE 2
Raman Bands of Graphite, Monolayer Graphene Reference,
and the Present Graphene containing composition

| | Raman | |
|---|---|---|
| Name of | Shift | |
| Band | (cm⁻¹) | Characterization of Band |
| D | 1346 | In plane vibration indicating multilayered |
| | | intact crystalline graphene with few defects. |
| G | 1573 | Vibration within the plane of the honeycomb |
| | | graphene layers in multilayered graphene and |
| | | graphite. |
| D′ | 1614 | Indicating the existence of multilayered |
| | | pristine graphene. |
| 2D | 2688 | Overtone band of D |
| Graphite | 2719 | Graphite Band |
| Band | | |
| D + G | 2922 | Indicating the existence of multilayered |
| | | pristine graphene. |

As noted above, pristine graphene may contain monolayer graphene (honeycomb lattice), multilayer graphene (for example less than 10 layers), or a combination of both. In FIG. 1(a), the spectrum of graphite has a sharp high peak G band, a weak G* band, and an overlapping band around 2700 cm⁻¹ consisting of a weaker 2D band and the 2719 cm⁻¹ graphite band. Also in FIG. 1, the spectrum of a monolayer of graphene has a sharp G band, a weak G* band, and a sharp 2D band.

Raman spectrum in FIG. 2 indicates that the carbon-oxygen bonds in graphene oxide create lots of defects resulting in more intense D band and broader D and G bands. The large number of defects leads to much broader but less intense 2D band due to the greater number of combination of modes caused by the defects.

Raman spectrum in FIG. 3 indicates that the present graphene containing composition is a mixture of graphene and graphite. The characteristic bands of each component are discussed above. The presence of D, D′, and D+G bands suggests that the graphene in the present invention is in the form of multilayered graphene. The percentage of graphene in the present composition is determined by comparing peak intensity (area under the curve) of D′ band with peak intensity of G band. It is believed that D′ band and G band in FIG. 3 quantitatively represent the relative amount of graphene and graphite, respectively, in the present composition. Due to the nature of graphene being individual layers of graphite carbon content and the same atomic structure, the possibility exists far more graphene is contained with the G peak than what appears in the D′ shoulder of the G peak. This D′ graphene portion appearing at the base of the G peak belongs to graphene. The D′ small peak at the base of the G peak merges to the left into the high G peak indicating both multilayered graphene but also the potential for substantial volumes of this multilayered graphene to exist hiding in the G peak of the Raman spectroscopy. This would result in a potential graphene content of up to 90% and 10% graphite. Further research still needs be done to determine the precise ratio of graphene to graphite in the invention's composite mix that comes directly from processing using this exemplary formula (Example 1). The result of data analysis shows that the present graphene containing composition contains at least 10.5% of multilayered graphene. This is shown by comparing the height of D′ band to the G band. The percentage of multilayered graphene in the present invention can be higher.

### Example 3. SEM and STEM Scanning

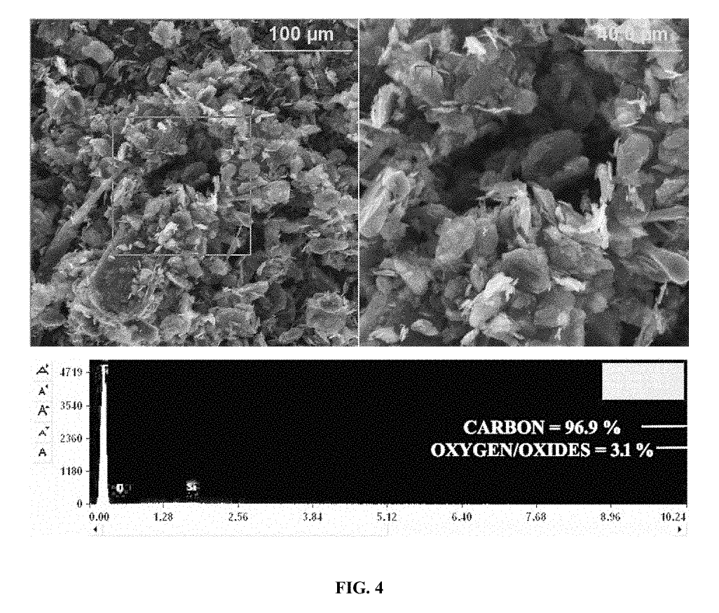

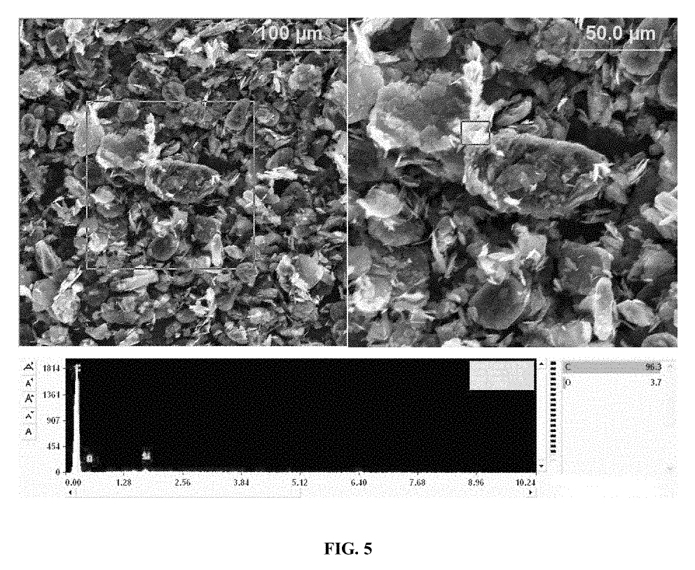

SEM tests on the graphene containing composition obtained in Example 1 are depicted in FIG. 4 and FIG. 5. Results in FIG. 4 show graphene atomic sampling analysis with 96.9% carbon and 3.1% oxygen/oxide. Second scan of the same sample, FIG. 5, shows graphene atomic sampling analysis with 96.3% carbon and 3.7% oxygen/oxide. Both FIG. 4 and FIG. 5 clearly show the presence of graphene and graphite flakes.

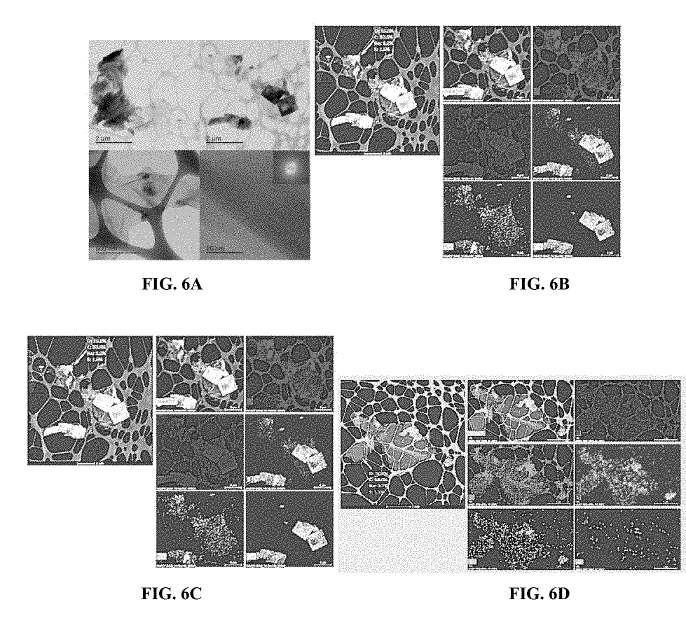

SEM and STEM scans were performed on the reference graphene oxide sample. The photos taken in both experiments are depicted in FIG. 6. SEM scans in FIG. 6(a) clearly show that the reference graphene oxide compound has poor crystallinity. The reference graphene oxide contains platelets of large sizes. STEM scans, FIG. 6(b)-(d), show that oxygen distribution in the reference material is localized and oxygen content ranges from about 16% to about 30% by weight. The reference material also contains relatively high level of Na₂SO₄ and CaSO₄, which could have contaminated the product during synthesis.

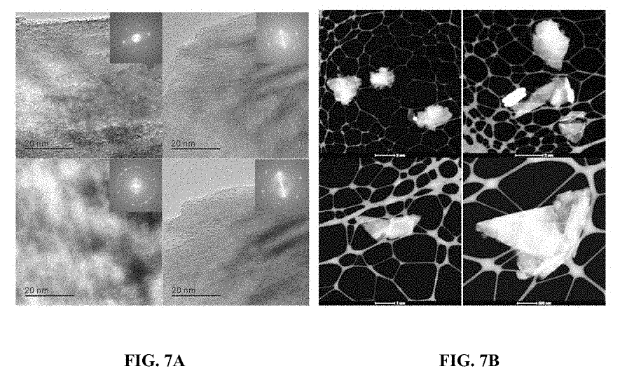

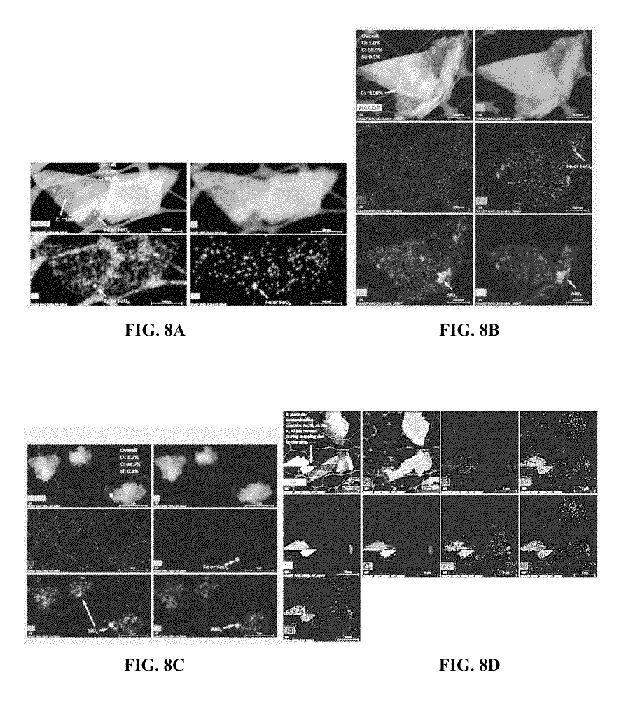

SEM and STEM scans were performed on the present graphene containing composition obtained in Example 1. The photos taken in both experiments are depicted in FIG. 7 and FIG. 8. SEM scans as in FIG. 7(a) show that the graphene containing composition contains flakes with very good crystallinity. STEM scans as in FIG. 7(b) show that the graphene containing composition contains mainly small flakes of sub-micron to a few microns in size and can be well dispersed in solvents. FIG. 8(a)-(d) show that oxygen level in the present graphene containing composition is very low, only about 1% by weight. It is believed that such low level of oxygen is close to background level of oxygen in the sample and/or in the starting material, indicating that the present graphene containing composition is substantially free of oxygen. As opposed to reference graphene oxide, FIG. 8(a)-(d) indicate that the present graphene containing composition only contains trace amount of Fe, Si, Al, Na, Mg, which is probably from debris of processing tools but presumably not a concern for its applications due to their low levels.

Examples 2 and 3, in combination, show that the graphene component in the present invention is in the form of multilayered graphene. This multilayered graphene is essentially and substantially free of oxygen and contains very low level of contaminants, such as Fe, Si, Al, Na, and Mg. The multilayered graphene also provides very good crystallinity. Therefore, it is believed that the multilayered graphene in the present graphene containing composition is in pristine condition. It appears that the cosolvent of ionized distilled water and acetone in tandem with graphite disrupts interlayer van der Waals forces, which allows the graphene layers to shear off and separate from the larger graphite substrate with gentle agitation instead of the normal industry methods of harsh mechanical exfoliation. Standard mechanical exfoliation, on the other hand, tends to damage the crystals in graphene as it bends and twists the graphene layers. The current invention distinguishes itself from the original Murray-Smith open source graphene formula in several important ways. The first is that the present invention uses ionized water as opposed to deionized water in the original open sourced formula. Further in the present invention, the ionized distilled water provides extra electrons in the cosolvent and the presently improved formula is blended under partial or full vacuum. This creates an ionic solution that is important to the mass fraction formula described herein. The original Murray-Smith open source formula specifically uses de-ionized water, which does not create an electrolytic solution. In the present invention, the use of ionized water was specific for creating an ionic solution to disrupt the interlayer van der Waals forces between the graphite layers, thereby weakening these electrostatic forces and allowing the graphene layers to cleave away from the graphite stacked layers with gentle agitation. The current process directly produces pristine graphene layers (mono and/or multilayered graphene) that have intact crystals and hexagonal shape.

This electrolytic reduction of the invention uses a single small headed mixing blade that induces the solvent and graphite solution to gently vortex in a mixing vessel, instead of sonication. Sonication is actually too harsh on the crystalline structure of the graphene layers as they break away from the graphite. This can be seen in the use of sonication for the breaking up of kidney stones in kidneys through a water medium (Lithotripsy). The substitution of gentle vortex mixing in place of sonication is a significant improvement over the original open source formula, and is based on avoiding the damage that occurs to the crystals in the graphene that otherwise occur from non-gentle agitation of any sort in the creation of graphene from graphite. In one embodiment, when the present graphene containing composition is mixed with 325 mesh graphite, the finished graphene composite powder, when mixed into paints and coatings, can be applied as a spray, whereas the original Murray-Smith formula required exfoliation. The original open source graphene ink prepared by Murray-Smith method is an ink not designed for mixing into other materials nor to become a powder graphene additive. The graphite mesh powder particles used in the invention rub up against each other causing gentle agitation, which only minimally impact each of the graphite particles in the process. Gentle agitation allows each individual graphene layer to maintain its crystalline structure and produces graphene flakes that are almost pristine as seen in scanning electron microscope tests.

These significant improvements to the original open source formula allow for the mass production of high quality multilayered graphene at low cost with intact crystallinity as described herein, which is a major achievement and improvement to current industry standards. These improvements in the current embodiments of the invention provide maximum use of the benefits of graphene properties. The embodiments herein make it possible to produce high quality large volume multilayered graphene with intact crystals, which is a new achievement and product category in the graphene industry. When mixed into materials, it has no pinholes or fisheyes. The material is sprayable and readily bindable, is hydrophilic in most liquids, and is producible at low cost. The current multilayer graphene is less hydrophobic and predominantly hydrophilic than other commercial graphene products on the market. No other graphene or graphene oxide product currently for sale in the industry has these combinations of features and benefits all in one graphene containing product. The current principal embodiment has additional benefits that, in comparison to single layer graphene, multilayer graphene is able to conduct heat and electrons on multiple axes (i.e. in three dimensions).

### Example 4. Applications of the Graphene Containing Composition

A. Preparation of Coating, Paint, or Concrete

The present graphene containing composition in both liquid and powder form (containing equivalent of 2 grams of the graphene containing composition powder) can be mixed into 50 ml (or equivalent weight) of paint or coating. Suitable ratios between the graphene containing composition powder and paint/coating range from about 1/99 to about 99/1. The present graphene containing composition can be used as an additive to concrete, cement, and other concrete byproducts (collectively “concrete”). Suitable ratios between the graphene containing composition powder and concrete range from about 1/99 to about 99/1 depending on the target uses of concrete. Existing graphene oxide industry standards are a 1% to 4% loading of graphene oxide into materials and liquids weight by weight or by volume depending on the material or liquid. It is anticipated that the current graphene containing composition should have similar loading ratios.

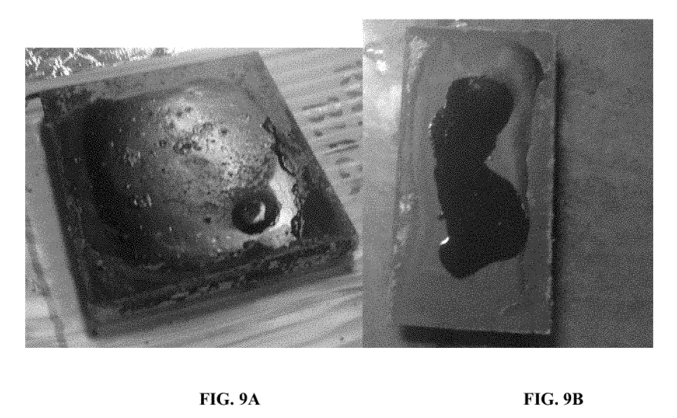

In another embodiment, the graphene containing composition powder is mixed with polyurea, polyurethane and anti-corrosion paints. The untreated anti-corrosion paint, applied to a metal surface alone, is unable to prevent acid corrosion on the surface of the metal. When the graphene containing composition powder is infused into the same anti-corrosion coating, the graphene infused anti-corrosion coating is surprisingly capable of preventing acid corrosion on the metal surface. Specifically, after the graphene infused anti-corrosion coating is sprayed onto the same metal surface, the later sprayed acid could only pool and eventually evaporate from the metal surface without damaging the surface. The effect of the acid on the metal surface covered with regular anti-corrosion coating is depicted in FIG. 9(a), wherein bubbling and eating away is observable. On the contrary, there is no observable damage on the same metal surface covered with the graphene infused anti-corrosion coating. In both tests, both coatings, with/without graphene containing composition, were heat cured before acid testing. Both metal surfaces were exposed to acid for 7 days. The enhanced anti-corrosion ability of the graphene infused coating is unexpected. Without being bound by any theory, it is believed that the reduced amount of defects in the present graphene containing composition, such as pinholes/fisheyes, contribute to the enhanced anti-corrosion ability of the modified paint.

B. Preparation of Faraday Film/Paint/Coating

The present graphene containing composition can be applied in the creation of an excellent faraday film, coating, or paint that has excellent properties at low cost for the EMP protection of anything or object it shields. In one embodiment, the present graphene containing composition, liquid or powder, may be blended with an adhesion promoter. Subsequently, the blend may be painted, sprayed, or coated to any material in order to prevent EMP pulses from penetrating the Faraday coating/film in any direction. Field tests of this embodiment indicate that harsh electromagnetic waves, including gamma rays, x rays, and other radio waves, were entirely eradicated. An optimal blend between the graphene containing composition (liquid or powder) and adhesion promoter is 2 grams of graphene containing composition powder in every 50 ml of adhesion promoter. An adhesion promoter is used as an additive or as a primer to promote adhesion of coatings, inks, or adhesives to the substrate of interest. An adhesion promoter usually has an affinity for the substrate and the applied coating, ink, or adhesive. Without the adhesion promoter, the properties of the applied coating may not be sufficient to meet the performance requirements of the end product, such as a painted automotive plastic surface. In automotive coatings, the term adhesion promoter refers to the primer, which achieves adhesion of the subsequent paint layer to substrates in general, including Thermoplastic Polyolefin. This adhesion promoter is usually composed of chlorinated polyolefin (CPO) as the active adhesion-promoting component, other resins, and pigment.

C. Preparation of Capacitor and Battery Materials

The present graphene containing composition can be blended with zinc, zinc oxide, other materials such as sulfides, copper oxides, or a combination thereof to create a quick charging super capacitor material that can be incorporated into many products that use batteries or capacitors. In one embodiment, the mixtures of the graphene containing composition and zinc and/or zinc oxide creates a fast charging capacitor material, which is capable of slowly releasing its electrons or electrical charge like a battery. Therefore, the blended material functions both as a battery and also a capacitor. Another super capacitor composition having the current graphene containing composition comprising blending charcoal, graphene, and zinc oxide together into an electrolyte to form a super capacitor that also behaves as a battery with both slow release of energy and a quick charging time.

D. Oil Spill Recovery

The present graphene containing composition has been tested in bench lab modeling with both fresh and salt water and crude oils representing a typical oil spill scenario. In one embodiment, 10 grams of graphene containing composite powder was added all at once into a water bucket containing oil and readily soaked up the oil, and cleared the water surface of oil, forming conglomerations of graphene capsules holding the oil and not allowing it to disperse into the water. The outside of the graphene conglomerations appeared as an encapsulation containing the liquid oil inside and the outside shell of the capsule appeared to be oil free. In this embodiment, the graphene containing composition became hydrophobic in contact with the oil, and floated on the surface allowing the graphene to be scooped and skimmed off the surface of the water with ease with an estimated 90% recovery of the oil in the water bucket. This graphene oil mix was collected and then later pressed to recover the oil, allowing the graphene containing composition to be reused multiple times (approximately 6 reuses before oil degradation). It was found that 1 gram of this graphene containing composition absorbed up to 68 grams of oil in its first use with slight degradation up to the 6^{th} use. A sharp decrease in its ability to absorb oil from water was found to occur at the 7^{th} reuse point.

The present multilayered hydrogen graphene can strengthen rubber and polymers and its performance in improving elasticity of rubber and polymer products. (http://pubs.acs.org/doi/abs/10.1021/nn901934u).

E. Replacement of Silicon in Solar Panels

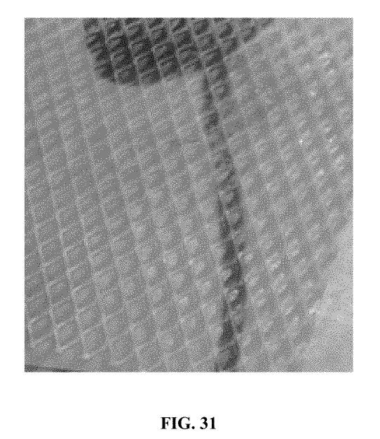

The present graphene containing composition can be used as a replacement for silicon in the manufacture of solar panels. Standard silicon solar panels convert 1 photon into 1 electron which is then sent to be stored in a battery. Standard industry solar panels are of low efficiency in converting photons into electrons. Researchers have contended, in the literature, that, when absorbed into graphene, an incoming photon can be converted into multiple electrons, a massive increase in efficiency. In one embodiment of testing with this graphene containing composition, tests were conducted by spray painting this graphene composite with adhesion promoter and without exfoliation on corrugated plastic panels. A normal solar panel is regarded to have an approximate efficiency of 14% in converting photons to electricity. Metered tests calculated out to a minimum 60% efficiency with some readings as high as 80%. The present graphene containing composition and hydrogen bonded multilayered graphene composition can be painted onto flexible plastic or other materials, and then twisting-torqueing the conductive graphene film as well as using a squiggly shape to engender a simple transistor effect and creating a very highly efficient energy harvesting panel for both heat and light energy harvesting. In one embodiment, a simple mesh collector with diodes or graphene leads harvests the electrons from both the pristine and hydrogen graphene films that are set between two insulating materials, one clear to allow light to pass and be captured by the graphene films, and one clear or solid as a base insulator material. In one embodiment, solar cells painted with graphene containing composition provide an efficiency of 60% in converting heat or light into electricity. In another embodiment, solar cells painted with multilayered hydrogen bonded graphene composition provide an efficiency of 80% in converting heat or light into electricity. The embodiments of both types of solar cells are illustrated in FIG. 31.

The graphene composite solar panels, as shown in FIG. 31, harvested electrons even in the dark after the sun had set. Without being bound by any theory, it is believed the graphene solar panels were either harvesting infra-red radiation or possibly harvesting static electricity from the Schumann-Tesla Cavity. These electrons produced a trickle charge metered at 240 volts through the panels covered by this graphene composite invention. These tests were conducted with no light from the sun at 12:00 AM midnight, and with no visible light available from any other sources. This graphene composite invention acted in such a way as to absorb electrical energy with almost no ohms' resistance.

Method of Making Multilayered Hydrogen Graphene Composition

The current multilayered/laminate graphene composition has been manufactured by placing the improved multilayered graphene formula to rest in situ in solvent mix for a longer soak time than the non-hydrogenated graphene formula allowing the ionic solvent solution to begin infiltrating (intercalating) into the graphite layers. This longer soak time of 8 to 24 hours before mechanical mixing allows the graphite layers to begin intercalating ions (positive charges) into the graphite crystal structures in the form of hydrogen, calcium, and nitrogen bonds that expand or replace the van der Waal gap and forces between layers. After soaking in the liquid solvent solution, the solution is then mechanically mixed, in one preferred embodiment at 13,000 RPM for 1 to 3 hours to create multilayered hydrogen graphene. Multiple batches were made and then tested to establish the best mix times based on each batch representing different intercalation time periods. These batches were then tested to establish maximum quality and best practices of the different batches and the winner chosen by selection after review during SEM lab time. This method is suitable for mass production. In one embodiment, the multilayered hydrogen graphene can be made in batches up to 1-5 kilograms every 3 hours of mixing with just one mix head and a small vessel mixing machine.

Properties of Multilayered Hydrogen Graphene Composition

When dried, the above graphite powder with average flake size about 44 microns at the beginning of production is transformed into about 3% hydrogen bonded graphene and about 97% hydrogen bonded graphite. Specifically, the 3% graphene is intercalated with hydrogen bonds and has an average flake size about 3 microns. The 97% graphite is also intercalated with hydrogen bonds and has an average flake size about 20 microns.

SEM studies at 4D labs at Simon Fraser University confirmed that the 3% graphene portion contains about 2 to 8 layers, and the 97% “graphite” portion contains about 20 to 40 layers of graphene sheets intercalated and stacked on each other. Both portions are intercalated with the Van der Wall forces weakened and enlarged space between all the graphite layers. Testing results show that (University of Singapore) the observed intercalation is caused by hydrogen bonds and the entire mass of both graphene and graphite portions are all behaving as multilayered graphene with hydrogen bonding throughout the entire mix. Each layer is a graphene sheet, but the graphite are stacked as multilayered graphene upon each other.

The aforementioned ionic solvent formula combined with a pre-mixing soak time of 8 to 24 hours in the solvent solution allows an increased intercalating to occur between the layers in all the graphite stacks. This intercalation period is then finished with mechanical high-speed shearing, which produces a multilayered hydrogen graphene comprising both graphene and graphite portions. Both portions are intercalated with hydrogen and other doping variants including, for example, calcium, nitrogen, boron, flourene, potassium, lithium and sulphur. The current multilayered/laminate hydrogen graphene is suitable for mass and low cost production.

In the current invention, the substitution of distilled water for de-ionized water, and the addition of iso alchohol into the solvent creates an ionic solution that if allowed to interact with the graphite powder over a longer period soak time produces multilayered hydrogen graphene. When graphite powder flakes are placed in this solution for from about 8 to about 24 hours, large amounts of hydrogen begin to intercalate in between the layers of graphite. The longer the intercalating period, the more intercalating hydrogen and potential doping of nitrogen and calcium occurs as the ionic solution reaches further into the center of the graphene sheets. When this mixture is then mechanically shear mixed at high (or low) RPM, the hydrogen intercalated graphite layers then slide off each other during mechanical mixing.

Applications of Multilayered Hydrogen Graphene Composition

The present multilayered hydrogen graphene composition has at least the following applications:

(1) Berry Phase Quantum Switch Gate

A future application of present multilayered hydrogen graphene is proposed based on the added properties that come from having hydrogen intercalated in the present graphene-multilayered/laminate graphene. In one embodiment, hydrogen bonded multilayered/laminate graphene can be functionalized as a Berry Phase Switch that allows electrons to move to a higher energy level when the quantum switch is turned on in the multilayered graphene painted or printed circuit. It is extremely electrically and thermally conductive even when mixed into other materials. Hydrogen is already known to grant graphene a form of super conductivity for electrons. In Berry Phase Gate application, a multilayered hydrogen graphene painted or 3D Printed circuit is laid down on various substrates. The hydrogen intercalation in the present invention directly creates a magnetic field into the graphene sheets.

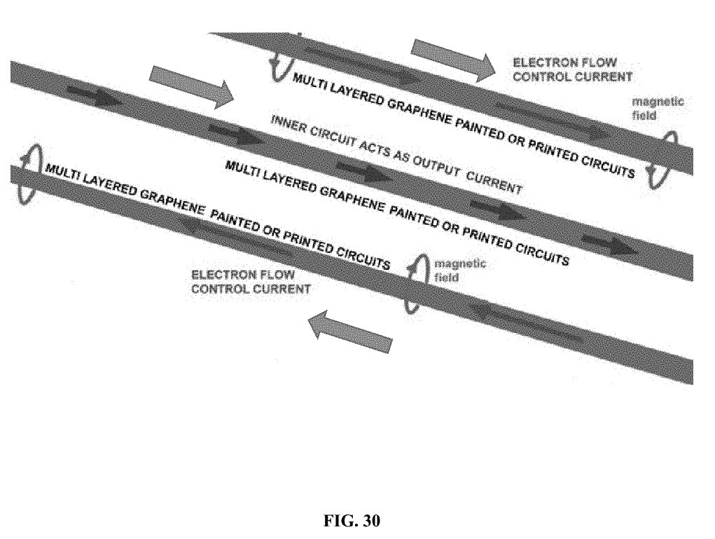

The magnetic field in between the multiple layers of graphene creates a natural tunnel effect and a self-contained channel for electrons moving in the clockwise direction. In clockwise circulation the electrons have a tight orbit. In counter clockwise orbits, the magnetic field has the opposite effect, pulling the electrons into wider orbits for electron movement. At a critical magnetic field strength, the field acts as a Berry Phase Switch. The counter clockwise orbits of the electrons twist causing the charged particles to execute clockwise vortexes near the boundary of graphene layers. In the counter clockwise movement of electrons, and at a critical energy level, a Berry Phase switches on for the electrons, which switches on when these magnetically induced vortexes are triggered. The multilayered hydrogen graphene based Berry Phase Switch is illustrated in FIG. 30.

When the Berry Phase is switched on, orbiting electrons abruptly jump to a higher energy level. The present multilayered hydrogen graphene naturally functionalizes this Berry Phase Switch into a simple application just by increasing the current flow in a counter clockwise direction until the Berry Phase Switch turns on and the electrons jump to a higher energy level in the hydrogenated graphene multilayers.

(2) Spintronic Induction Based Transistor with Multilayered Graphene Hydrogen Intercalated or Doped with Additional Calcium and/or Nitrogen

A proposed multilayered hydrogen bonded graphene spintronic switch functions as a logic gate. As electric current moves through 2 outside wires, it creates a magnetic field that wraps around the wires. (Shown in FIG. 30). In addition, a magnetic field near a third painted or 3D printed circuit in between the 2 outer graphene painted circuits affects the current flowing. Silicon-based computers transistors cannot use this method. Instead, they are connected by wires. The output from one transistor is connected by a wire to the input for the next transistor.

In the proposed “graphene” induction transistor, electrons moving through multilayered hydrogen bonded graphene create a magnetic field that affects the flow of current in a nearby graphene painted or printed graphene circuit, providing cascaded logic gates made of the same hydrogen bonded multilayered graphene that are not physically connected.

Because the interaction between each of the graphene painted or printed wires or circuits takes place through an electromagnetic wave via induction, this should functionalize an induction based tera hertz transistor effect using multilayered hydrogen graphene with or without calcium or nitrogen doping or intercalation. In addition, these graphene circuits can be made smaller than silicon-based transistors, which are close to their size limit due to silicon's limited material properties.

(3) Superconducting of Electricity at Room Temperatures

Hydrogen in graphene has been shown to increase electron mobility at room temperature to levels that are considered to be Super Conducting by creating a magnetic field: (http://science.sciencemag.org/content/352/6284/437).

Tests on the present graphene with hydrogen intercalation and/or calcium and nitrogen doping with painted or 3D printed circuits indicate that electrical conduction in such circuits is very fast, which is from about 0.00001 to about 0.000214 Siemens per meter.

(4) Superior Electrical Conductivity Through Calcium Doping

Calcium doping into both graphene and graphene shows superior performance in electrical super conductivity through doping of calcium atoms into the graphene crystals. Multilayered hydrogen graphene can have calcium doping. The electrical conductivity tests show very fast electron mobility in the multilayered hydrogen graphene that may or may not include calcium and or nitrogen doping. (http://nanotechweb.org/cws/article/tech/62590)

(5) Computing

The present multilayered hydrogen graphene can replace copper wiring in circuits in computer chips and other electrical devices. It may also be used to contain copper wiring to prevent degradation. In this application copper circuits are laid down on silicon, and then a thin coating of graphene is deposited on top. This process has been tested by Stanford engineers with generic graphene products (https://motherboard.vice.com/en_us/article/qkv9kd/a-cheap-graphene-upgrade-could-boost-computing-speeds-by-30-percent-2)

The present multilayered hydrogen graphene can conduct electricity at high speed without heat build-up and can be produced at very low cost. (FIG. 36). Furthermore, the present multilayered hydrogen graphene in painted or 3D printed form presents transistor effects and can be used to replace silicon transistors for the computing industry.

(6) Sensors

The present multilayered hydrogen graphene composition can be mixed into various materials to produce low cost but very accurate sensors. For example, the present multilayered hydrogen graphene composition mixed in clay or in plastic putty can be used as effectiveness and low-cost heart rate sensor.

(7) Embedded Electronics

The present multilayered/Laminate graphene can be used for embedded electronics including electrically conductive threads for clothing, printed plastic flexible electric circuits that can replace circuit boards, copper wiring, and various other embedded electronics.

(8) 3D Ink Printing

The present multilayered hydrogen graphene composition presents superior performance in 3D printing of electrical circuits on flexible plastics as it has hydrogen, calcium and/or nitrogen doping. Hydrogen creates a magnetic graphene which helps to superconduct electricity. Nitrogen adds structural strength, also a benefit over regular graphene in many applications including 3D printing. Calcium doping in graphene also helps with increased electrical conductivity and sensitivity.

The present multilayered hydrogen graphene composition can be added to various types of 3D printer liquids to create electrically conductive and structurally strong 3D Printed materials.

(9) Superior Elastic/Flexibility Properties of Multilayered/Laminate Graphene

The present multilayered hydrogen graphene composition may increase elasticity of other materials. In one embodiment the present multilayered/laminate graphene passes those elastic properties onto multiple materials that absorb the multilayered hydrogen graphene as a powder additive. These materials range from metals and alloys to plastics, foams, concrete, coatings, and paints. Applications are, but not limited to, structural cement, automotive applications, composites, sporting goods, and protective equipment. (https://www.researchgate.net/publication/47524305 Elastic properties of hydrogenated graph ene)

(10) Superior Strength Properties of Multilayered/Laminate Graphene

The present multilayered hydrogen graphene composition can increase strength of other materials including plastics, foams, concrete, coatings, automotive application and composites, including sporting goods and protective equipment.

(11) Boiler Interior Coating-Refactory Material

One embodiment of current invention relates to a multilayered hydrogen graphene refactory cement that lasts longer inside boilers protecting the steel from the flame combustion effects. The refactory mix can resist and insulate much higher temperatures than industrial standard refactory cement mixes currently on the market.

(12) Friction Coatings

The present multilayered hydrogen graphene composition can be used in place of greases, and as poly urea grease and other anti-friction methods. The present multilayered hydrogen graphene composition is able to handle high heat without breaking down and to maintain a slick surface for materials to interact against each other without friction and heat build-up. In one embodiment, the present multilayered hydrogen graphene composition can used as coatings that can maintain the surface coarseness in the presence of high and torturous heat to continue operating in having a friction surface that needs high abrasion surfaces to withstand such heats and forces. An example is the braking surface for brake shoes or dry clutches in the automotive industry.

(13) Steel

The present multilayered hydrogen graphene composition gives steel not only added structural strength, but also new levels of flexibility to stop metal or steel brittleness. The present multilayered hydrogen graphene composition also grants the steel both suppleness and new levels of ductability. (https://www.nature.com/articles/srep02086)

(14) Rubber & Polymers

(15) Heat Exchangers

In one embodiment, the present multilayered hydrogen graphene composition was found to outperform the best existing thermally conductive materials used for heat exchangers. Heat exchangers or pipes conducting fluids, including water, can be coated internally with multilayered hydrogen graphene or graphene using sacrificial resins. The addition of multilayered hydrogen graphene composition in boiler and sealed heating/cooling units such as air conditioning, cooling towers, HVAC, radiators, and boilers can seal damage, increase heat/cool transfer abilities, reduce maintenance requirements, and increase system life and system durability.

(16) Filtration

In one embodiment, the present multilayered hydrogen graphene composition was found to outperform the graphene containing composition as described above in collecting and filtering environmental hazardous wastes such as mercury and oil in water. In the embodiment, the mercury and oil in water were successfully captured and about 95% of waste was successfully removed from water. The present multilayered hydrogen graphene composition should provide excellent desalination capacity for filtering water and at low cost. Graphene containing composition has been demonstrated as an effective desalination agent. Multilayered/laminate graphene composition with hydrogen bonds and calcium and or nitrogen doping should increase the removal of waste in water at a very economical cost. (https://www.sciencedaily.com/releases/2015/03/150325210330.htm)

(17) Medical Applications

The present multilayered hydrogen graphene composition is suitable for medical uses including bacteria killing surface coatings, spinal column repair shunts, wearable sensors, internal low-cost sensors, disease detection, cancer treatment, drug delivery,

(18) Supercapacitors

Hydrogen bonded graphene offers superior performance for supercapacitors and industrial energy storage. The hydrogen bonds create extra surfaces for electron storage thereby increasing energy storage capacity in the same physical space. (https://link.springer.com/article/10.1007/s10853-016-0055-9?no-access=true). We have built several prototype super capacitors with the hydrogen bonded graphene at its core and found superior performance.

(19) Building Products

The present multilayered hydrogen graphene composition can be used in the building industry to strengthen and seal and to efficiently transfer heat. Applications include uses in roofing, flooring, heating tiles, paint with a R value for insulation, fire retardant coatings, and waterproofing coatings.

(20) Concrete and Steel Infrastructure

The present multilayered hydrogen graphene composition can be used in concrete and steel infrastructure including steel ridges and concrete bridge repair. On steel bridges, following rust conversion application, the present multilayered hydrogen graphene composition can be applied to add protection, durability, to strengthen the entire structure, and to save on future maintenance. In concrete applications, the present multilayered hydrogen graphene composition can strengthen the concrete, reducing water damage and minimizing deterioration.

(21) Pipeline Uses

The present multilayered hydrogen graphene composition can be applied to pipelines as an anti-corrosion and protective coating and as an efficient thermal heat ribbon (thermal veining or heat coating) to assist the flow oil and other liquids within the pipeline.

(22) Maritime Uses

The present multilayered hydrogen graphene composition can be applied as a sub-surface paint in maritime uses to reduce friction, increase speed and reduce fuel consumption. Also, the present multilayered hydrogen graphene composition can prevent biological growth on the hull surface in conjunction with the application of a weak electrical current as low as 1.5 amps. The present hydrogen graphene composition can be used in ship cathodes.

(23) Anticorrosion

The present multilayered hydrogen graphene composition can be used as a coating to protect against rust and salt providing better maintenance intervals. The present multilayered hydrogen graphene composition can be applied to ships, mining uses, oil storage tanks, rail and other transport, concrete, docks and shoreline, and other infrastructure.

(24) Military Uses

Among military applications, the present multilayered hydrogen graphene composition can provide EMP protection from magnetic pulse weapons. The present multilayered hydrogen graphene composition can mask radar and detection signatures on aircraft, naval vessels and communication centers. As a baked paint coating, it can increase armor protection on military vehicles and essentially function as an anti-blast coating.

(25) Data Protection

The present multilayered hydrogen graphene composition can shield against data hacking by presenting a painted barrier that prevents reception of RF modulation signals.

(26) Hydro-Electric Uses

The present multilayered hydrogen graphene composition can be applied in electric production and distribution infrastructure, including coating of wires, capacitors, and improving efficiency in power generating equipment through its superconductive properties, thermal properties, anti-friction properties and strength properties. Examples of such applications include strengthening electrical poles and towers.

(27) Additive in Poly Urea Grease

Hydrogen graphene composition was blended with poly urea grease and test results showed that, with the presence of hydrogen graphene composition, the bonding in poly urea was stable and maintained chemical bonds under stretching and pressure testing.

(28) Application to Glass

The present multilayered hydrogen graphene composition can be added to glass as a replacement for indium tin oxide which generates heat retention benefits in cold environments and air conditioning and cooling retention benefits in warm environments.

(29) Optical Enhancement

The present multilayered hydrogen graphene composition can be used to optimize optical properties such as conductance, reflection and transmission properties.

(30) Steel Protection

The present multilayered hydrogen graphene composition can be applied to the surface of steel as a paint coating or bonded to Soloxane or other chemicals as a protective coating for steel. The composition can also be considered for steel production to improve ductibility during two brittle production phases, Kappa-carbide, K-carbide, & B2 intermetallic.

(31) U/V Protection

The present multilayered hydrogen graphene composition can be applied in coatings as a U/V protection.

(32) Graphitic Polymer

The present multilayered hydrogen graphene composition can be developed into a graphitic polymer.

(33) Coatings

The present multilayered hydrogen graphene composition can be used to enhance the properties and durability of polyurea, polyurethane, epoxies, resins, elastomers, polyesters and other composites.

(34) Concentrates and Dispersions

The present multilayered hydrogen graphene composition can be developed as a primary additive to other products as an improvement by developing concentrates and dispersions. For example, some materials cannot have solid particles added. It found that hydrogen graphene composition can be added to various liquid coatings and adhesives, and then as concentrates and dispersions can be mixed into these powder prohibitive materials.

(35) Ceramic Strength Through Baking

Hydrogen graphene composition can be further strengthened by baking a graphene coating application in an oven or heating elements in a production line for about 20 minutes at 350 degrees. The anti-corrosion properties of the baked hydrogen graphene composition were tested when mixed into anti-corrosion paints. This forms a tough ceramic coating, protecting and adding strength to its substrate. In the absence of a heat tunnel, a chemical heat reaction may be used where heating elements cannot be used practically. The Chemical heat reaction is caused by a product source that engenders an exothermic reaction in tandem with hydrogen graphene composition to use such as on an existing steel bridge application.

The present multilayered hydrogen graphene composition, method of its preparation, characterization of the multilayered hydrogen graphene composition, and applications of the multilayered hydrogen graphene composition may be further understood in connection with the following Examples and embodiments. In addition, the following non-limiting Examples and embodiments are provided to illustrate the invention.

### Example 5. Method of Manufacturing Hydrogen Bonded Graphene Composition

The method of manufacturing multilayered hydrogen graphene is the same as Example 1 except that the soaking time of graphite in the ionic solvent solution is from about 8 hours to about 24 hours before mechanical mixing.

### Example 6. SEM Side View of Multilayered Hydrogen Graphene Composition

SEM imaging was accomplished by placing hydrogen graphene flakes on their side in special mounting slides-mounting rigs used for side viewing samples at 4D Labs Simon Fraser University.

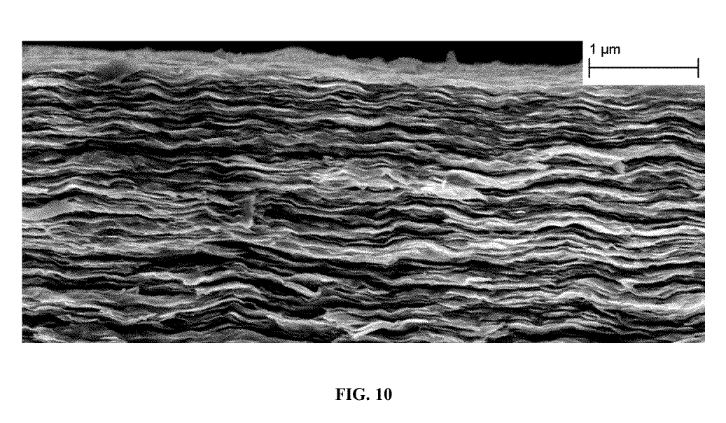

The SEM side view of the multilayered hydrogen graphene composition is illustrated in FIG. 10. Layers are counted by close up examination during scanning electron microscope operation and by viewing samples on computer screens.

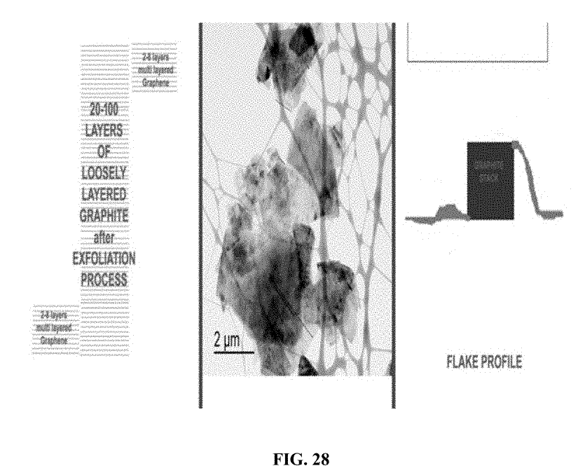

The middle panel of FIG. 28 shows that the stacks of 20 to 40 layered graphene were breaking away at the top and the bottom and those segments of break away graphene were still attached to the larger 20-40 layered stacks of intercalated graphite. The top and bottom layers that had come away but still attached to the larger stacks were 2-6 layers of graphene, while the larger stacks were intercalated graphite stacks of 20 to 40 layers (some of these flakes up to 100 intercalated layers). This is the basis of the diagrams based on the top view SEM picture included in FIG. 28. The lighter shaded smaller flakes in the middle picture are 2-6 layers, the darker flakes are 20 up to 40 intercalated layers with some flakes up to an intercalated 100 graphene layers (4D Labs, Simon Fraser University, Canada)

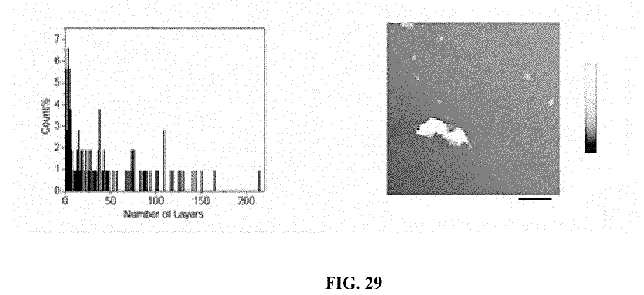

The thickness of hydrogen bonded multilayered graphene composition was also examined by AFM (University of Western Ontario). The test results, depicted in FIG. 29, reveal that graphene in the present hydrogen graphene composition contains 1 to 10 layers and that the graphene content is at least of 3.6% by volume.

### Example 7. Sputtering Plasma Testing

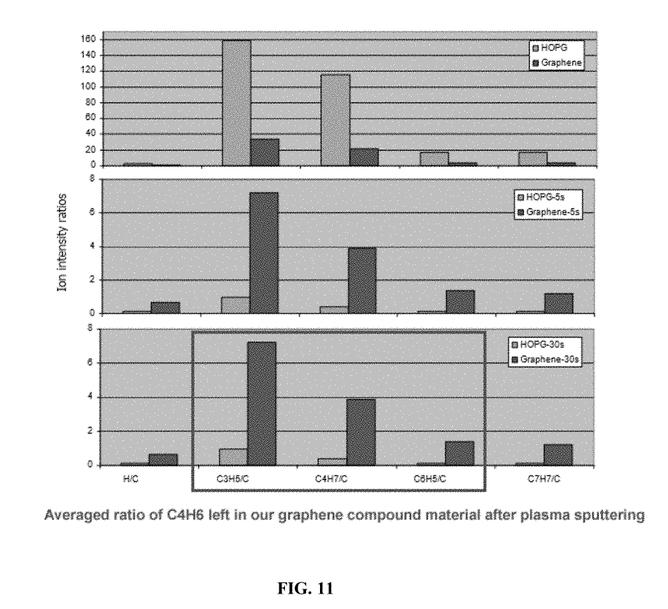

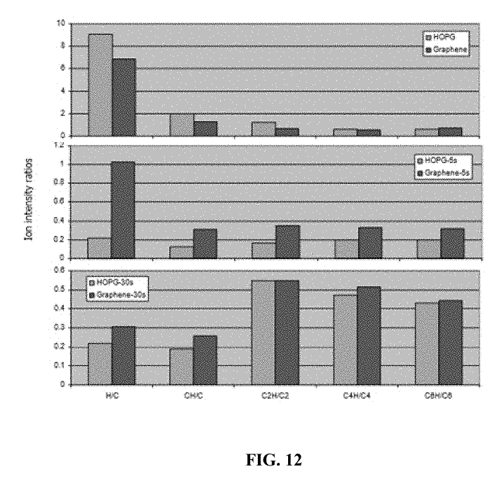

Sputtering plasma tests burns off surface hydrogen in initial, 5 second, and 30 second increments. Tests were conducted with reference graphite sample (HOPG) and the present multilayered hydrogen graphene composition from Example 5. Test results are depicted in FIG. 11 (obtained by the University of Western Ontario) and FIG. 12 (obtained by the University of Singapore).
a) Both FIGS. 11 and 12 indicate that the hydrogen atoms are intercalating. The ratio of hydrogen atoms to carbon atoms is 1 hydrogen atom for every 10 carbon atoms representing 2 graphene crystals. Similarly, the ration of nitrogen atoms to carbon atoms is 2 nitrogen atoms for every 10 carbon atoms representing 2 graphene crystals.
b) The test results from the University of Western Ontario (FIG. 11) show an average empirical formula of C4H6 calculated as an average of the longest sputtering time revealing an empirical formula in that sample.

### Example 8. Elemental Analysis of Multilayered Graphene Composition

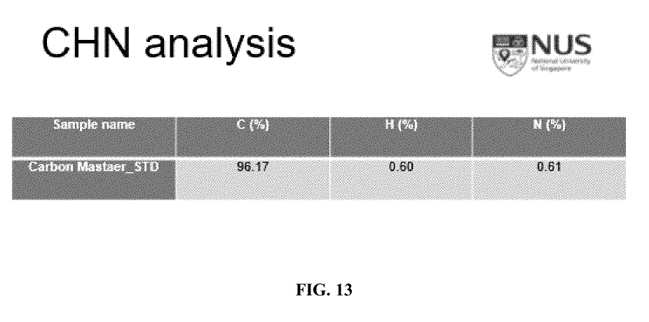

Elemental analysis was performed for the multilayered hydrogen graphene composition obtained in Example 5. (The University of Singapore). The test results indicate that the multilayered hydrogen graphene composition contains about 96.17% carbon, 0.60% hydrogen, and 0.61% of nitrogen. (FIG. 13). The test results demonstrate the existence of both hydrogen and nitrogen intercalation in the multilayered graphene composition. The nitrogen is being sourced from the distilled water (used for ionic solution in Examples 1 and 5) that still has ammonia, nitrites, or nitrates in it after the distillation process. Normalized by molecular weight of each type of atoms, elemental analysis shows that there is about 1 hydrogen atom for a range of 8 to 12 carbon atoms in the multilayered hydrogen graphene composition.

### Example 9. Intercalation of Calcium

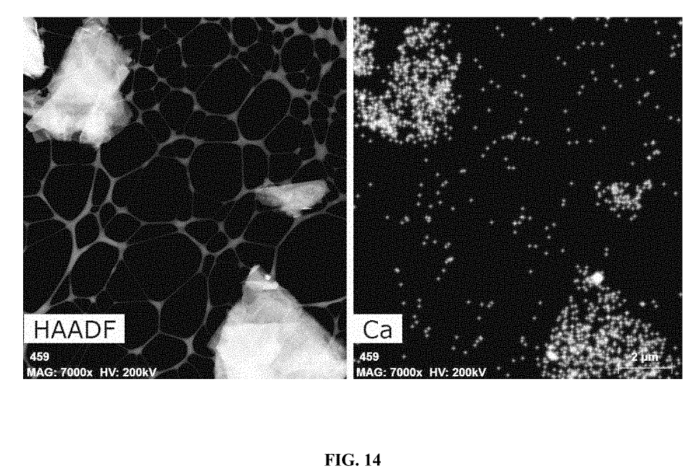

SEM scans (OSIRIS scanning electron microscope with element analysis) were performed for the multilayered hydrogen graphene composition obtained in Example 5. (4D Labs, Simon Fraser University, Burnaby, BC, Canada). The scan results are depicted in FIG. 14. Right side of FIG. 14 shows that calcium has doped or intercalated into the graphene flakes suggesting that calcium is doped into graphene crystals. The calcium is being sourced from the distilled water (used in the preparation of ionic solution in Examples 1 and 5) that still has calcium in it after the distillation process. The calcium is likely to be intercalated in between layers and on the surface of flakes.

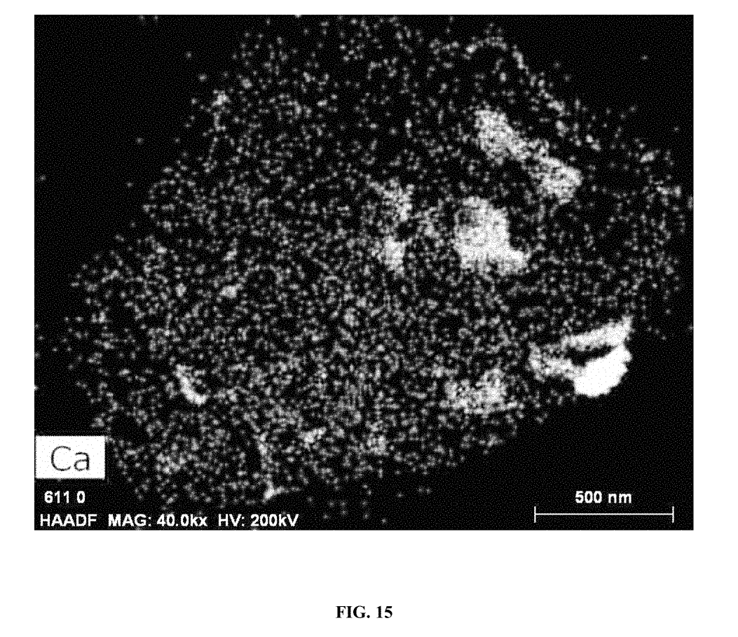

Additional STEM scans of calcium doped-intercalated into multilayered hydrogen graphene composition is depicted in FIG. 15. (4D Labs, Simon Fraser University, Burnaby, BC, Canada). The STEM imaging with elemental test capability (OSIRIS SEM machine, SEM Explorer, and STEM analysis machines) allows for samples to not only be imaged by electron microscope scanning, but very quick elemental analysis is also tested by the specialty STEM scanners.

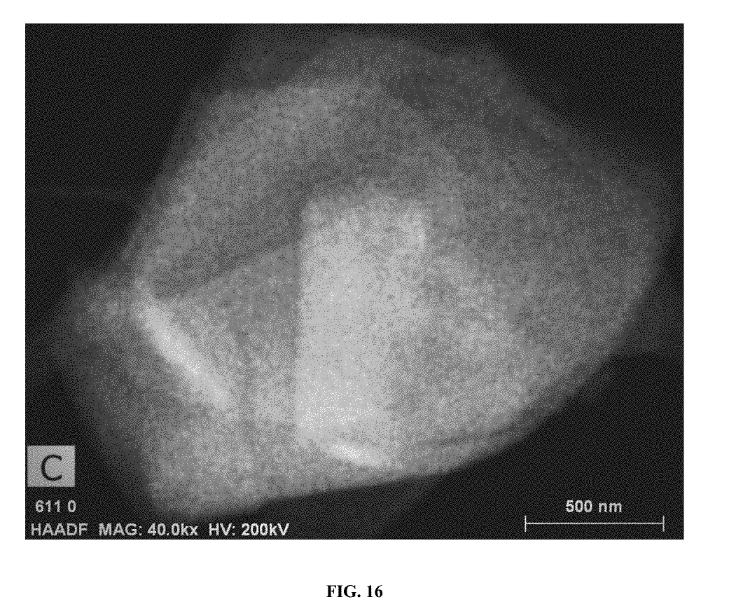

Carbon SEM scan of multilayered hydrogen graphene flake is depicted in FIG. 16. (4D Labs, Simon Fraser University, Burnaby, BC, Canada). FIG. 16 shows the shape of flake and borders of calcium scan in FIG. 15.

### Example 10. SEM of Multilayered Hydrogen Bonded Graphene Composition

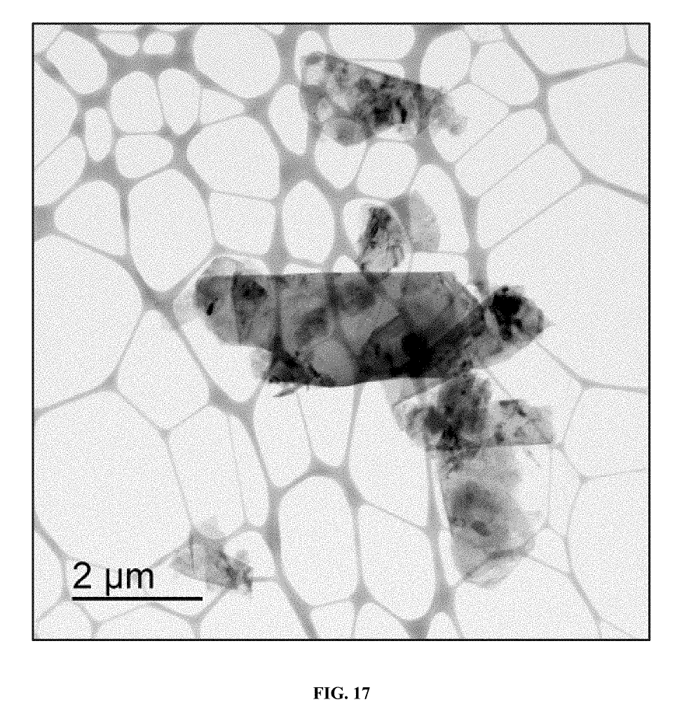

SEM scanning was performed for the multilayered hydrogen bonded graphene prepared according to the method in Example 5. The scan results are depicted in FIGS. 17-19. (4D Labs Simon Fraser University, Burnaby, BC, Canada)

In FIG. 17, flakes are attached at edges in an almost half loop layout, which may explain its bonding abilities as both small and large flakes operating with large surface areas for materials to grab onto when mixed into various materials. In actual measurements taken, the dark color flakes are 20 to 100 layers of loose Van Der Waal forces graphite intercalated with hydrogen thus behaving as multilayered graphene with hydrogen bonds between layers. The lighter gray flakes are 2 to 8 layered graphene flakes normally still attached to the larger graphite-graphene stacks. This effect is repeated throughout all samples tested and is described as a homogenous sampling of hydrogen bonded graphene well distributed throughout all samples tested.

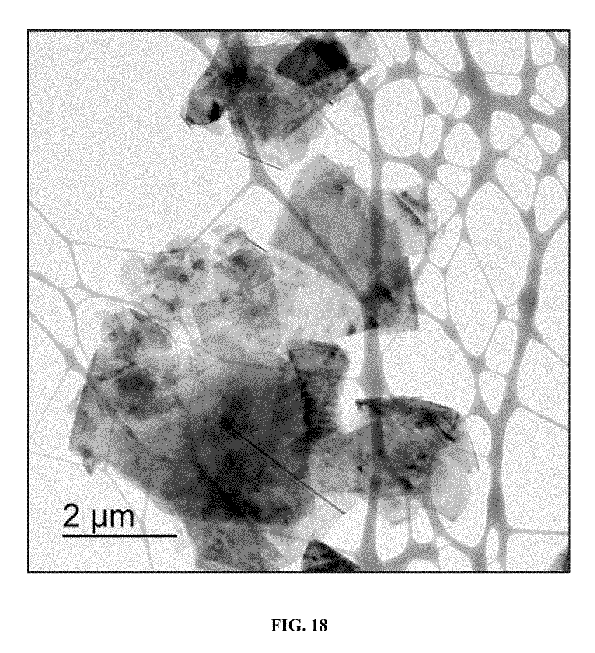

FIG. 18 indicates that the 2-8 layered graphene flakes still attached to the larger 20 to 40 to 100 layered stacks of graphite-graphene-graphene. All the layers of graphite have partially separated due to the above intercalation process that creates hydrogen or positive charged bonds between the layers. The illustrated 20 to 40 to 100 layered graphite stacks are loosely stacked after processing and have taken on the properties of graphene in tandem with the actual 2 to 8 layer of multilayered graphene that have folded off the graphite stacks. The actual layers were counted and could be clearly seen to count in close up SEM imaging mode when in close up imaging view with a measurement tool in the SEM OSIRIS scanning machine.

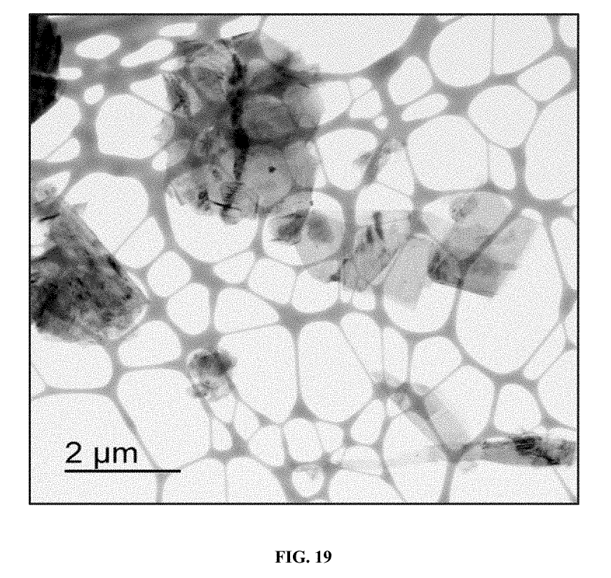

FIG. 19 exhibits the same pattern of multilayered hydrogen graphene that has folded off the larger flakes but are still attached creating excellent binding capacity and quick dispersion into materials without aggregating or clumping. The interconnection between 2-8 multilayered graphene and the hydrogen bonded loose stacks of graphene produce amazing electrical conductivity of this graphene composition.

### Example 11. NMR Studies of Multilayered Hydrogen Graphene Composition

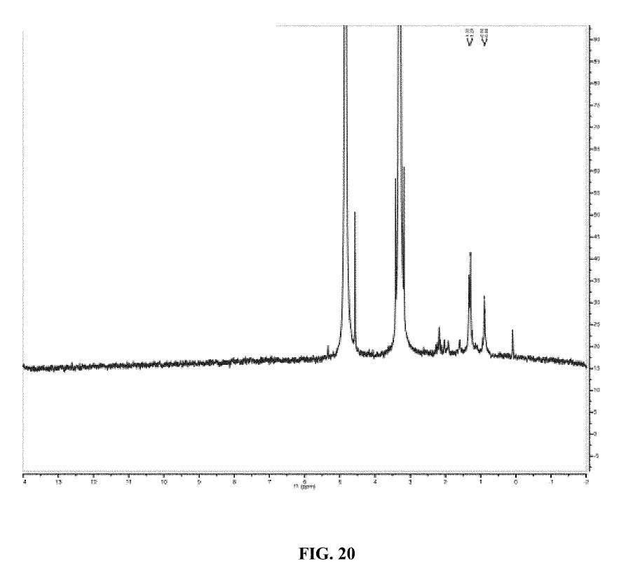

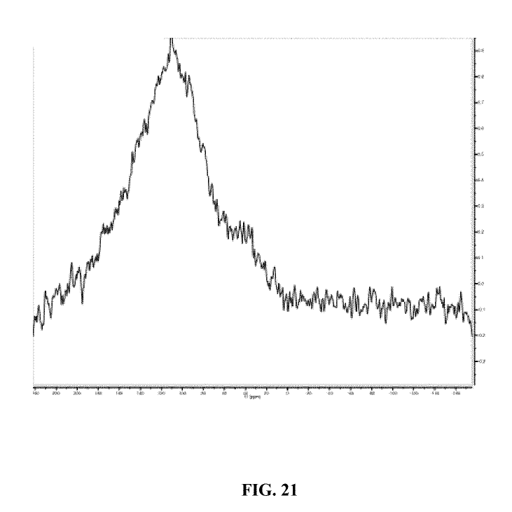

The multilayered hydrogen graphene composition produced in Example 5 was dissolved in deuterated methanol and its proton and carbon NMR spectra were subsequently collected. (Agilent DD2 600 MHz spectrometer, the University of Toronto). The proton and carbon NMR spectra are depicted in FIGS. 20 and 21, respectively.

A few weak and broad signals were observed in the proton NMR spectrum (FIG. 20). Lines at 1.3 and 0.9 ppm were previously observed in 3D micro-assembly of graphene sheets prepared by reduction of graphite oxide. These lines can be attributed to C—O—H groups, indicating the existence of hydrogen bonding.

Presence of multiple lines from C—O—H groups suggest that there are several magnetically inequivalent C—O—H sites but their detailed structures could not be resolved by NMR methods. Attempts to collect 2D NMR spectra from these samples were unsuccessful due to paramagnetic nature of the sample (paramagnetic electrons shorten NMR relaxation times).

Paramagnetic nature of samples also confirmed by Carbon NMR spectrum, where very broad peak at approximate 110 ppm was observed. This line also similar to previously observed C-13 lines from sp² Carbons in 3D graphene microassembly. (See M. C. Worsley et al. Mechanically robust 3D graphene macroassembly with high surface area. Chem. Commun. (2012), vol. 48, pp. 8428-8430.) On the right shoulder small additional peak or peaks at approx. 45 ppm can be observed, but could not be resolved due to overlap with intense and broad graphene peaks. These might be from C—O—H (usually observed at ˜50 ppm) in graphene prepared from graphite oxide by reducing the epoxy group C—O—C. However, epoxy group would produce C-13 line at −75 ppm and in these samples it could not be resolved.

### Example 12. Electron Mobility and Resistance and Conductivity of Multilayered Hydrogen Graphene Composition

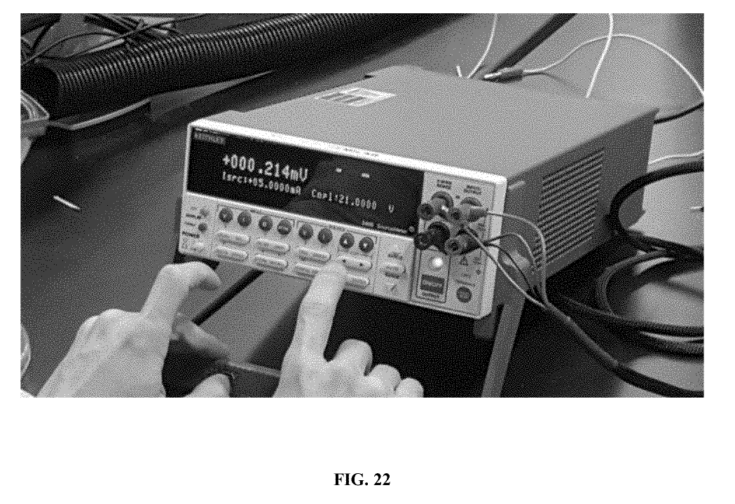

The present multilayered hydrogen graphene composition was painted as a circuit. Its conductivity and electrical resistance were subsequently measured. (FIG. 22; Keithley, Model 2400 SourceMeter®, Onami Lab, University of Oregon, Eugene, Oreg., USA). The experimental readings for conductivity and resistance are about 2.14×10⁻⁴ Siemens per meter and about 0.1 Ohm·cm, respectively.

The test results unexpectedly show that the present multilayered hydrogen graphene composition is incredibly conductive. As a reference in all engineering manuals, copper wiring has a conductivity about 5.88×10⁷ Siemens per meter. Although graphene in general has higher ohms surface sheet resistance than copper, the conductivity of present multilayered hydrogen graphene composition is magnitudes faster than copper in an electrical circuit as the current is moving through the multilayered hydrogen graphene layers, not just the surface.

The present multilayered hydrogen graphene composition appears to be a non-Ohmic material, and does not follow ohms law of inverse resistance and conductivity. The present multilayered hydrogen graphene is not temperature dependent for its conductivity as it is not a thermistor.

In field of graphene research, the flat, hexagonal lattice of graphene offers relatively little resistance to electrons, carrying electricity better than superb conductors such as copper, and is almost as good as superconductors. Unlike superconductors, which need to be cooled to low temperatures, graphene's remarkable conductivity works even at room temperature. The electrons in graphene have a longer mean free path than they have in any other material. The present multilayered hydrogen graphene composition is a strong, light, and relatively inexpensive material that can conduct electricity with greatly reduced energy losses. The present multilayered hydrogen bonded graphene is magnetic and the magnetic field tunnel effect may be attributable to the enhanced conductivity.

Unlike many graphene commercial products, the present multilayered hydrogen graphene continues to be electrically conductive even after being mixed into coatings for printing-spray painting as electrical circuits.

### Example 13. General Applications of Multilayered Hydrogen Graphene Composition

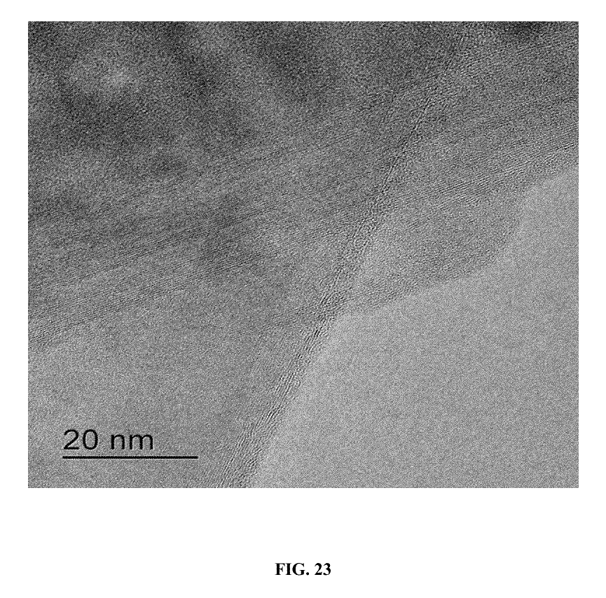

The instant multilayered hydrogen graphene composition has been mixed into concrete, corrosion paints, metals, and made into an electrical circuit that can be spin coated or spray painted onto computer chips. It is normally hydrophilic in all tests and easily mixes into and then binds with incredible hardness into materials. FIG. 23 illustrates one embodiment, in which the instant multilayered hydrogen graphene composition was mixed with water and tested on wafers. (4D Labs Simon Fraser University, Burnaby, BC, Canada).

As shown in FIG. 23, the mixture has well dispersed and distributed equally throughout the water. The lighter shade material on the right is graphene, the darker shade material is hydrogen intercalated 20 to 100 layered graphite stacks that are loosely stacked with hydrogen bonds separating the individual layers and functionalized as multilayered/laminate graphene. The grooved lines in the middle of the scan are similar to transistors that have been made in other graphene research.

### Example 14. Multilayered Hydrogen Bonded Graphene Composition as Circuit

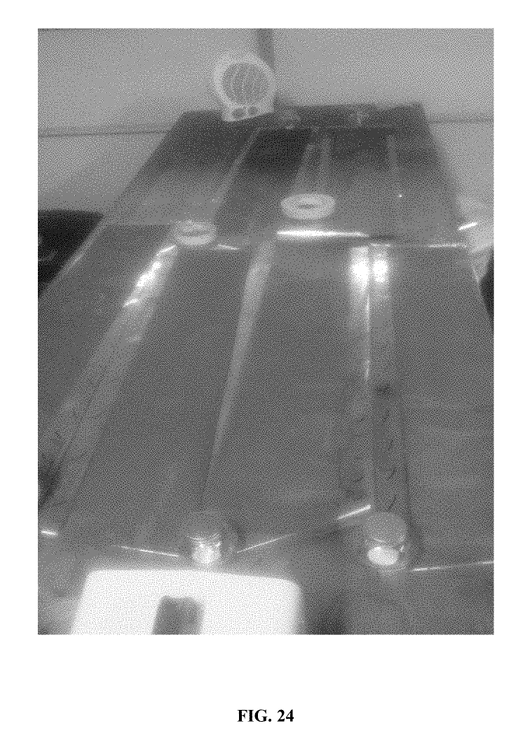

The present multilayered hydrogen graphene composition was painted onto plastic sheets as a circuit. The device is illustrated in FIG. 24. Voltage meter with 2 probes was used on flexible plastic sheets painted with the present hydrogen graphene composite. They were tested both flat and then tested when pressure or twisting was applied to the plastic sheets. The experimental results reveal a 4-5 millivolt electrical delay in the multilayered hydrogen bonded graphene circuit when the device was torqued or bent into a squiggly shape. This delay of current is already known in electrical engineering as a transistor or semi-conductor effect. Notably, a 0.5 millivolt delay is the minimum required for a transistor effect.

### Examples 15. Uniformity of Graphene Crystals (Pristine Crystals) in the Multilayered Hydrogen Graphene Composition

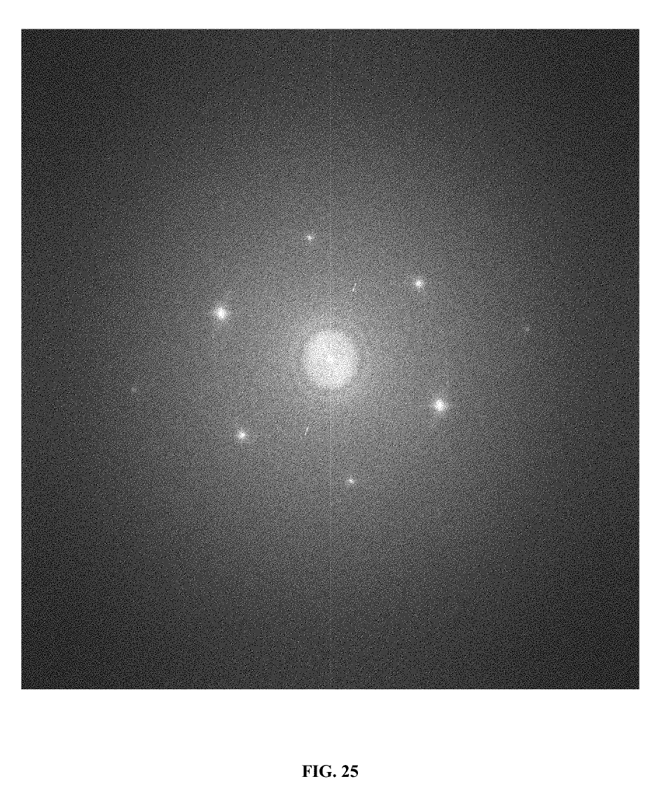

As shown in FIG. 25, intact high quality crystals were found uniformly distributed throughout both the loose layered hydrogen bonded graphite stack flakes (about 20 to 100 layers) and layered graphene flakes (about 2 to 8 layers). The testing results show that graphene crystals were uniformly intact throughout all production batches. (4D Labs Simon Fraser University, Burnaby, BC, Canada).

### Example 16. Characterization of Multilayered Hydrogen Graphene Composition Under Frozen Conditions

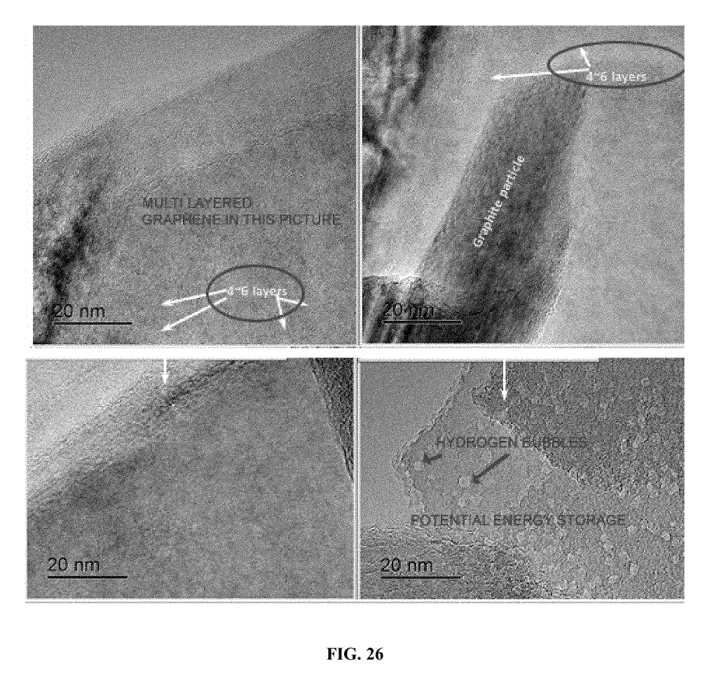

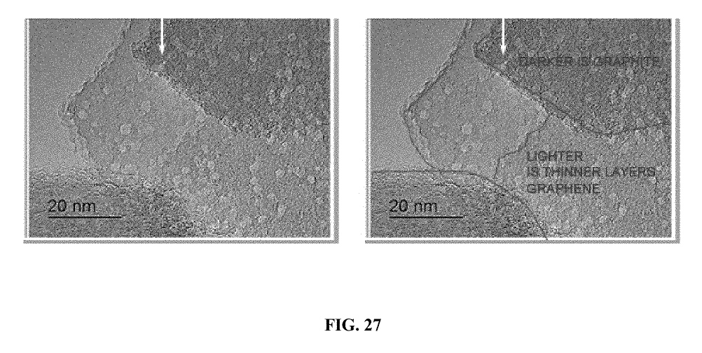

The present multilayered graphene composition was frozen to −32° C. and SEM scans of the frozen samples are depicted in FIGS. 26 and 27. (4D Labs Simon Fraser University, Burnaby, BC, Canada). In FIG. 26, hydrogen bubbles among frozen graphene sheets can be identified. (i.e. arrows in lower right panel). Frozen step during manufacturing causes hydrogen to separate from graphene layers and the separated hydrogen then forms hydrogen bubbles between graphene sheets. The left panel of FIG. 27 is the reference SEM scan. The right panel of FIG. 27 depicts the way the layers inter-stack with each other consistently like a deck of playing cards creating interlocking sheets of multi layered graphene. This self-forming mechanism in the hydrogen graphene when it is mixed into water or other materials explains why it has no fisheyes or holes for corrosion to occur in the layers of the invention graphene. The sheets are attracted to each other at the edges and consistently are drawn together at the edges whenever mixed into liquids or materials. In the same figure, the circular hydrogen bubbles can be seen all over the graphene sheets.

We claim:

1. A graphene containing composition comprising:
(a) a graphene component; and
(b) a graphite component
wherein the graphene component comprises monolayer graphene, multilayered graphene, or a combination thereof,
further wherein the multilayered graphene comprises less than about 10 layers of carbon atoms, and
wherein the composition comprises at least about 3.5% of the graphene component.

2. The graphene containing composition of claim 1, wherein the amount of oxygen in the composition is less than about 4% by weight.

3. The graphene containing composition of claim 1, wherein the amount of oxygen in the composition is less than about 1% by weight.

4. A method for using graphene containing composition comprising the steps of:
(a) providing the graphene containing composition; and
(b) adding the graphene containing composition to a product selected from the group consisting of paints, coatings, cement, concrete, steel, plastics, a sealant, an anti-corrosion agent, an anti-weathering agent, a salt water shield, an anti-fouling agent, a conductivity enhancing agent, a thermal insulation barrier, an electromagnetic pulse barrier, a radio frequency modulation barrier, a magnetic levitation agent, a fire resistant agent, a heat conductor, a battery, a capacitor storage, adhesion promoters, anti-friction additives, flooring, ships hulls, sporting goods, a fire retardant, a de-icing agent, solar panels, electronic circuits, sensors, and an insulation material.

5. The method of using graphene containing composition of claim 4, wherein the product is a solar panel,
wherein the solar panel is coated with graphene containing composition, and
wherein photon-electricity conversion efficiency is more than about 60%.

6. A method of making a graphene containing composition comprising:
mixing isopropyl alcohol, acetone, distilled water, and graphite water to form a graphite suspension;
high speed blending the graphite suspension at a temperature of at least about 120° F. from about 1 hour to about 10 hours;
applying vacuum to the graphite suspension during blending;
heating the graphite suspension during blending; and
drying the blended graphite suspension to obtain the graphene containing composition;
wherein the distilled water is ionized water.

7. The method of making a graphene containing composition of claim 6, wherein the blending speed is about 13000 rpm.

8. The method of making a graphene containing composition of claim 6, wherein the graphite suspension is optionally cavitated.

9. The method of making a graphene containing composition of claim 6, wherein the graphite suspension is optionally sonicated.

10. The method of making a graphene containing composition of claim 6, wherein the ratio among isopropyl alcohol, acetone, distilled water, and graphite is 5:70:25:5 (v:v:v:w).

11. A multilayered hydrogen graphene composition comprising:
(a) hydrogen graphene; and
(b) hydrogen graphite
wherein the hydrogen graphene contains hydrogen intercalated with graphene layers,
wherein the hydrogen graphite contains hydrogen intercalated with graphite layers,
wherein the composition comprises at least 3% of hydrogen graphene,
wherein the hydrogen graphene contains from at least 2 layers of graphene to about 8 layers of graphene, and
wherein the hydrogen graphite contains from about 20 layers of graphite to about 100 layers of graphite.

12. The multilayered hydrogen graphene composition of claim 11, wherein the hydrogen graphene has an average flake size of about 3 microns, and wherein the hydrogen graphite has an average flake size of about 20 microns.

13. The multilayered hydrogen graphene composition of claim 11, wherein the multilayered hydrogen graphene composition optionally comprises intercalated nitrogen, intercalated calcium and other intercalated ions.

14. A printed or 3D printed circuit comprising the multilayered hydrogen graphene composition of claim 11, wherein the conductivity of the circuit is about 2.14×10⁻⁴ Siemens per meter and the resistance of the circuit is about 0.1 Ohm·cm.

15. A method for using multilayered hydrogen graphene composition comprising the steps of:
(a) providing the multilayered hydrogen graphene composition; and
(b) adding the multilayered hydrogen graphene composition to a product selected from the group consisting of a Berry Phase switch, a spintronic induction based transistor, a superconductor, sensors, embedded electronics, coating, concrete, cement, paints, an additive, composites, sporting goods, plastics, protecting film, friction coating, steel, rubber, polymers, thermally conductive materials, filtration materials, supercapacitors, building materials, an anti-corrosive agent, an electromagnetic pulse barrier, a radio frequency modulation barrier, wires, capacitors, glass, solar panels, and U/V protecting agents.

16. The method of using multilayered hydrogen graphene composition of claim 15, wherein the product is a solar panel,
wherein the solar panel is coated with the multilayered hydrogen graphene composition, and
wherein photon-electricity conversion efficiency is more than about 80%.

17. A method of making a multilayered hydrogen graphene composition comprising:
mixing isopropyl alcohol, acetone, distilled water to an ionic solvent
soaking graphite in the ionic solvent for from about 8 to about 24 hours to form a presoaked graphite suspension;
high speed blending the presoaked graphite suspension at a temperature of at least about 120° F. from about 1 hour to about 10 hours;
applying vacuum to the presoaked graphite suspension during blending;
heating the presoaked graphite suspension during blending; and
drying the blended graphite suspension to obtain the multilayered hydrogen graphene composition;
wherein the distilled water is ionized water.

18. The method of making a multilayered hydrogen graphene composition of claim 17,
wherein the blending speed is about 13000 rpm.

19. The method of making a multilayered hydrogen graphene composition of claim 17,
wherein the presoaked graphite suspension is optionally cavitated or sonicated.

20. The method of making a multilayered hydrogen graphene composition of claim 17,
wherein ratio among isopropyl alcohol, acetone, distilled water, and graphite is 5:70:25:5 (v:v:v:w).
